(19) United States
(12) Patent Application Publication
(10) Pub. No.: US 2025/0228116 A1
(43) Pub. Date: Jul. 10, 2025

(54) COLLOIDAL PARTICLE INK COMPOSITION, METHOD OF FORMING COLLOIDAL PARTICLE PATTERN BY USING THE SAME, COLLOIDAL PARTICLE PATTERNED FILM USING THE SAME, AND ELECTRONIC DEVICE INCLUDING COLLOIDAL PARTICLE PATTERN

(71) Applicants: UNIST (Ulsan National Institute of Science and Technology), Ulsan (KR); SOGANG UNIVERSITY RESEARCH & BUSNIESS DEVELOPMENT FOUNDATION, Seoul (KR)

(72) Inventors: Bong Soo KIM, Ulsan (KR); Hyobin Ham, Ulsan (KR); Moon Sung Kang, Seoul (KR); Chang Hyeok Lim, Gyeonggi-do (KR)

(73) Assignees: UNIST (Ulsan National Institute of Science and Technology), Ulsan (KR); SOGANG UNIVERSITY RESEARCH & BUSINESS DEVELOPMENT FOUNDATION, Seoul (KR)

(21) Appl. No.: 19/013,514

(22) Filed: Jan. 8, 2025

(30) Foreign Application Priority Data
Jan. 9, 2024 (KR) 10-2024-0003638
Jan. 7, 2025 (KR) 10-2025-0002060

(51) Int. Cl. H10K 71/12; B82Y 20/00; B82Y 40/00; C09K 11/02; C09K 11/08; C09K 11/88; G03F 7/00; G03F 7/11; G03F 7/36; H10K 50/11

(52) U.S. Cl. CPC H10K 71/12; C09K 11/025; C09K 11/0883; C09K 11/883; G03F 7/0035; G03F 7/11; G03F 7/36; H10K 50/11; B82Y 20/00; B82Y 40/00

(57) ABSTRACT

Disclosed herein are a colloidal particle ink composition, a method of forming a colloidal particle pattern by using the same, a colloidal particle patterned film, and an electronic device.

### CROSS-REFERENCE TO RELATED APPLICATION

This application is based on and claims priority under 35 U.S.C. § 119 to Korean Patent Applications No. 10-2024-0003638, filed on Jan. 9, 2024, and No. 10-2025-0002060, filed on Jan. 7, 2025, in the Korean Intellectual Property Office, the disclosure of which is incorporated by reference herein in its entirety.

### BACKGROUND

### 1. Field

The disclosure relates to a colloidal particle ink composition, a method of forming a colloidal particle pattern by using the same, a colloidal particle patterned film, and an electronic device.

This study was conducted with the support of the Samsung Future Technology Promotion Project (Project Number: SRFC-MA1901-51) and National Research Foundation of Korea (Project Numbers: 2021R1A2C2008332 and RS-2024-00445116).

### 2. Description of the Related Art

Colloidal particles have been extensively studied in recent years because of their potential applications in optoelectronic devices. For example, quantum dots, as an example of such materials, exhibit interesting physical properties including adjustable bandgaps, narrow bandwidths, high luminescence efficiency, and solution processability. However, developing a patterning process suitable for these solution-processed nanomaterials remains a challenge. Photolithography is one of the most promising techniques among the various available patterning methods, and is capable of producing high-resolution patterns that meet industrial requirements.

In conventional photolithography, a pattern is formed by physically or chemically etching a target material according to the characteristics of a pre-pattern of overlapping photoresists. In this process, the target material must withstand harsh etching conditions while maintaining its physical properties. However, the luminescence properties of nanostructured luminescent materials such as quantum dots may degrade during an etching operation due to defects created over a large surface area. In addition, conventional general direct photopatterning processes have been utilized as a promising lithographic approach to form patterns through selective chemical transformation of target layers and subsequent appropriate development operations, and do not include an etching operation. However, the high-energy irradiation and/or high-temperature heat treatments required for chemical transformation in direct photopatterning may raise concerns about potential damage to the intrinsic luminescent properties of nanostructured luminescent materials, especially, quantum dots. Additionally, quantum dot patterns formed by direct photopatterning have a disadvantage of low fidelity.

### SUMMARY

Provided a colloidal particle ink composition capable of forming a colloidal particle pattern with high fidelity. Provided are a method of forming a colloidal particle pattern using the colloidal particle ink composition and a colloidal particle patterned film formed using the same. Provided is an electronic device having excellent characteristics, which includes the colloidal particle pattern formed using the colloidal particle ink composition.

Additional aspects will be set forth in part in the description which follows and, in part, will be apparent from the description, or may be learned by practice of the presented embodiments of the disclosure.

According to one aspect of the disclosure, there is provided a colloidal particle ink composition including colloidal particles and a low-temperature-active crosslinker.

According to an embodiment, the low-temperature-active crosslinker may be thermally activated at a temperature of about 0° C. to about 130° C. or activated by ultraviolet light of about 200 nm to about 380 nm to produce an intermediate.

According to an embodiment, the low-temperature-active crosslinker may be a compound including a diazo group.

According to an embodiment, the low-temperature-active crosslinker may be a compound represented by Formula 1 below:

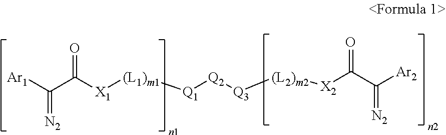

wherein, in Formula 1,
L₁ and L₂ are each independently a single bond or a C₁-C₃₀ alkylene group unsubstituted or substituted with at least one R₁,
m1 and m2 are each independently 1, 2, 3, 4, 5 or 6,
Ar₁ and Ar₂ are each independently a C₅-C₆₀ carbocyclic group unsubstituted or substituted with at least one R₁ or a C₁-C₆₀ heterocyclic group unsubstituted or substituted with at least one R₁,
n1 and n2 are each independently 0, 1, 2, 3, 4, 5, 6, 7, 8, 9, or 10,
a sum of n1 and n2 is 2 or more,
Q₁ to Q₃ are each independently a single bond, O, S, C, C(R₂), C(R₂)(R₃), or a C₁-C₃₀ alkylene group unsubstituted or substituted with at least one R₁,
X₁ and X₂ are each independently O, S, Se, N(R₄), or C(R₄)(R₅),
R₁ to R₅ are each independently hydrogen, deuterium, —F, —Cl, —Br, —I, a hydroxyl group, a cyano group, a C₁-C₃₀ alkyl group, a C₂-C₃₀ alkenyl group, a C₂-C₃₀ alkynyl group, a C₁-C₃₀ alkoxy group, a C₁-C₃₀ alkylthio group, a C₅-C₆₀ carbocyclic group, a C₁-C₆₀ heterocyclic group, or —Si(Q₁₁)(Q₁₂)(Q₁₃), and
Q₁₁ to Q₁₃ are each independently hydrogen, deuterium, —F, —Cl, —Br, —I, a hydroxyl group, a cyano group, a C₁-C₃₀ alkyl group, a C₂-C₃₀ alkenyl group, a C₂-C₃₀ alkynyl group, a C₁-C₃₀ alkoxy group, or a C₁-C₃₀ alkylthio group.

According to another aspect of the disclosure, there is provided a method for forming a colloidal particle pattern using the colloidal particle ink composition.

According to another aspect of the disclosure, there is provided a colloidal particle patterned film formed using the colloidal particle ink composition.

According to another aspect of the disclosure, there is provided an electronic device including a colloidal particle pattern formed using the colloidal particle ink composition.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 schematically illustrates a method of forming a colloidal particle pattern, according to an embodiment;

FIG. 2 illustrates photographs and height profiles of a colloidal particle pattern formed according to a method of forming a colloidal particle pattern, according to an embodiment, observed using an atomic force microscope (AFM);

FIG. 3 illustrates line edge roughness, line width variation and surface roughness of a colloidal particle pattern formed according to a method of forming a colloidal particle pattern, according to an embodiment;

FIG. 4 schematically illustrates a method of forming a colloidal particle pattern, according to an embodiment;

FIG. 5 illustrates a colloidal particle pattern according to an embodiment, observed using a fluorescence microscope;

FIG. 6 illustrates photograph and height profiles of a colloidal particle pattern formed according to a method of forming a colloidal particle pattern, according to an embodiment, observed using an AFM;

FIG. 7 illustrates optical microscope images of line patterns of CuInS, InAs, and PbS quantum dots formed according to a method of forming a colloidal particle pattern, according to an embodiment;

FIG. 8 is a cross-sectional view schematically illustrating an example of an electronic device according to an embodiment;

FIG. 9 illustrates emission spectra of an electronic device according to an embodiment; and

FIGS. 10 to 12 illustrate current density (J)-voltage (V)-luminance (L) profiles and external quantum efficiency (EQE)-J profiles of an electronic device according to an embodiment, respectively.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

Hereinafter, the disclosure will be described in more detail.

The terms “include” or “have” in this specification mean that a feature or component described in the specification is present, and do not preclude the possibility that one or more other features or components may be added.

When various components such as layers and films in this specification are said to be “on” other components, this includes not only cases where they are “directly on” other components, but also cases where other components are interposed between them.

### [Colloidal Particle Ink Composition]

A colloidal particle ink composition according to an aspect of the disclosure includes colloidal particles and a low-temperature-active crosslinker.

Since the colloidal particle ink composition includes the low-temperature-active crosslinker, the colloidal particles are crosslinked by the low-temperature-active crosslinker, and thus a crosslinking reaction may occur without heat treatment at a high-temperature (for example, a temperature exceeding 140° C.), thereby preventing a phenomenon of deterioration of luminescence characteristics or electrical characteristics due to damage of the colloidal particles in a solution process or a phenomenon of change or degradation of a morphology of the formed patterned thin film. In addition, since chemical crosslinking is formed in the colloidal particles, the particles have excellent chemical durability and/or resistance to a solvent, so that deterioration of previously formed patterns can be prevented even when photopatterning is repeated as needed, thereby forming a high-quality multi-color colloidal particle pattern.

According to an embodiment, the colloidal particle may have a shape such as a dot, a rod, a 2D plate, or a 3D object.

According to an embodiment, the colloidal particles may be quantum dots.

According to an embodiment, the quantum dot includes a semiconductor nanocrystal and an organic ligand bound to the surface of the semiconductor nanocrystal.

The semiconductor nanocrystal refers to a crystal of a semiconductor compound.

The semiconductor nanocrystal may include any material having semiconductor or conductor properties capable of emitting light of various emission wavelengths depending on its size.

According to an embodiment, the semiconductor nanocrystal may include a group III-VI semiconductor compound; a group II-VI semiconductor compound; a group III-V semiconductor compound; a group III-VI semiconductor compound; a group I-III-VI semiconductor compound; a group IV-VI semiconductor compound; a group IV compound; or any combination thereof.

According to an embodiment, the III-VI group semiconductor compound may include a binary compound (for example, In₂S₃, or the like), a ternary compound (for example, AgInS, AgInS₂, CuInS, CuInS₂, or the like), or any combination thereof.

According to an embodiment, the II-VI group semiconductor compound may include a binary compound (for example, CdS, CdSe, CdTe, ZnS, ZnSe, ZnTe, ZnO, HgS, HgSe, HgTe, MgSe, MgS, or the like), a ternary compound (for example, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, or the like), a quaternary compound (for example, CdZnSeS, CdZnSeTe, CdZnSTe, CdHgSeS, CdHgSeTe, CdHgSTe, HgZnSeS, HgZnSeTe, HgZnSTe, or the like), or any combination thereof.

According to an embodiment, the III-V group semiconductor compound may include a binary compound (for example, GaN, GaP, GaAs, GaSb, AlN, AlP, AlAs, AlSb, InN, InP, InAs, InSb, or the like), a ternary compound (for example, GaNP, GaNAs, GaNSb, GaPAs, GaPSb, AlNP, AlNAs, AlNSb, AlPAs, AlPSb, InGaP, InNP, InAlP, InNAs, InNSb, InPAs, InPSb, GaAlNP, or the like), a quaternary compound (for example, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, or the like), or any combination thereof.

According to an embodiment, the III-V group semiconductor compound may further include a II group element. For example, the III-V semiconductor compound further including a group II element may include InZnP, InGaZnP, InAlZnP, or any combination thereof.

According to an embodiment, the III-VI group semiconductor compound may include a binary compound (for example, GaS, GaSe, Ga₂Se₃, GaTe, InS, InSe, In₂Se₃, InTe, or the like), a ternary compound (for example, InGaS₃, InGaSe₃, etc.), or any combination thereof.

According to an embodiment, the group I-III-VI semiconductor compound may include a ternary compound (for example, AgInS, AgInS₂, CuInS, CuInS₂, CuGaO₂, AgGaO₂, AgAlO₂, or the like), or any combination thereof.

According to an embodiment, the IV-VI semiconductor compound may include a binary compound (for example, SnS, SnSe, SnTe, PbS, PbSe, PbTe, or the like), a ternary compound (for example, SnSeS, SnSeTe, SnSTe, PbSeS, PbSeTe, PbSTe, SnPbS, SnPbSe, SnPbTe, or the like), a quaternary compound (for example, SnPbSSe, SnPbSeTe, SnPbSTe, or the like), or any combination thereof.

According to an embodiment, the Group IV compound may include a single element compound (for example, Si, Ge, or the like), a binary compound (for example, SiC, SiGe, or the like), or any combination thereof.

According to an embodiment, the semiconductor nanocrystal may include CdS, CdSe, CdTe, ZnS, ZnSe, ZnTe, InP, InN, InAs, GaN, GaP, GaAs, ZnCdS, ZnSeS, ZnCdSeS, CdZnSe, InZnP, InGaP, GaPZnS, GaPZnSe, GaPZnSeS, or any combination thereof.

According to an embodiment, the semiconductor nanocrystal may have a diameter of about 1 nm to about 10 nm.

According to an embodiment, the semiconductor nanocrystal may have a core-shell structure including a core and a shell covering at least a portion of the core.

According to an embodiment, the shell of the quantum dot can serve as a protective layer for maintaining semiconductor properties by preventing chemical modification of the core and/or serve as a charging layer for imparting electrophoretic properties to the quantum dot.

According to an embodiment, the material included in the core and the material included in the shell may be different from each other.

According to an embodiment, the shell may be single-layered or multi-layered.

According to an embodiment, the interface between the core and the shell may have a concentration gradient in which the concentration of a specific element present in the shell decreases or increases toward the center.

The shell of the semiconductor nanocrystal may include the above-described III-VI semiconductor compound, II-VI semiconductor compound, III-V semiconductor compound, III-VI semiconductor compound, 1-III-VI semiconductor compound, or IV-VI semiconductor compound; an oxide of a metal or nonmetal; or a combination thereof.

According to an embodiment, the oxide of the metal or non-metal may include a binary compound (for example, SiO₂, Al₂O₃, TiO₂, ZnO, MnO, Mn₂O₃, Mn₃O₄, CuO, FeO, Fe₂O₃, Fe₃O₄, CoO, Co₃O₄, NiO, or the like), a ternary compound (for example, MgAl₂O₄, CoFe₂O₄, NiFe₂O₄, CoMn₂O₄, or the like), or any combination thereof.

According to an embodiment, the semiconductor nanocrystals may be synthesized by a wet chemical process, an organic metal chemical vapor deposition process, a molecular beam epitaxy process, or the like.

According to an embodiment, the full width of half maximum (FWHM) of the emission wavelength spectrum of the semiconductor nanocrystal may be about 45 nm or less. For example, the FWHM of the semiconductor nanocrystal may be about 40 nm or less or about 30 nm or less.

According to an embodiment, the semiconductor nanocrystal may have a shape such as a nanoparticle (for example, spherical, plate-shaped, pyramidal, multi-arm, cubic or the like), nanotube, nanowire, nanofiber, or the like.

According to an embodiment, the energy band gap of the quantum dots is controlled depending on their sizes, so that light of various wavelengths can be obtained.

According to an embodiment, the quantum dots may emit red, green and/or blue light.

According to an embodiment, by using quantum dots of different sizes, a light-emitting element that emits light of various wavelengths can be implemented, light of various colors can be combined to emit white light, and an element that absorbs light of various wavelengths in addition to white light can be implemented.

According to an embodiment, the organic ligand serves to protect the surface of the semiconductor nanocrystal and control the dispersibility in a solvent, and a commonly available organic ligand compound may be used as the organic ligand.

According to an embodiment, the organic ligand may include a C₄-C₃₀ fatty acid or a derivative thereof.

According to an embodiment, the organic ligand may include oleic acid, myristic acid, lauric acid, palmitic acid, palmitoleic acid, stearic acid, oleylamine, n-octyl amine, hexadecyl amine, trioctyl amine, octanethiol, dodecanethiol, hexyl phosphonic acid, n-octyl phosphonic acid, tetradecyl phosphonic acid, octadecyl phosphonic acid, or any combination thereof.

According to an embodiment, the low-temperature-active crosslinker may be thermally activated at a temperature of about 0° C. to about 130° C. to produce an intermediate. For example, the low-temperature-active crosslinker may be thermally activated at a temperature of about 20° C. to about 120° C. or about 50° C. to about 115° C. to produce an intermediate.

According to an embodiment, the low-temperature-active crosslinker may be activated by ultraviolet light to produce an intermediate. For example, the low-temperature-active crosslinker may be activated by ultraviolet light of about 200 nm to about 380 nm, about 300 nm to about 380 nm, about 254 nm, or about 365 nm to produce an intermediate.

According to an embodiment, the low-temperature-active crosslinker may be used in a colloidal particle pattern forming method to be described below. For example, the low-temperature-active crosslinker may be used in a photoresist-guided indirect photopatterning method.

According to an embodiment, the low-temperature-active crosslinker may be used in a direct photopatterning method.

According to an embodiment, the low-temperature-active crosslinker may be a compound including a diazo group. For example, the diazo group may induce carbene-mediated crosslinking by annealing as exemplified below.

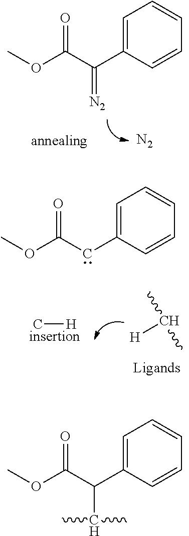

According to an embodiment, the low-temperature-active crosslinker may be a compound represented by Formula 1 below:

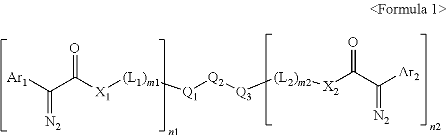

wherein, in the Formula 1,
L₁ and L₂ are each independently a single bond or a C₁-C₃₀ alkylene group unsubstituted or substituted with at least one R₁,
m1 and m2 are each independently 1, 2, 3, 4, 5, or 6,
Ar₁ and Ar₂ are each independently a C₅-C₆₀ carbocyclic group unsubstituted or substituted with at least one R₁ or a C₁-C₆₀ heterocyclic group unsubstituted or substituted with at least one R₁,
n1 and n2 are each independently 0, 1, 2, 3, 4, 5, 6, 7, 8, 9, or 10,
a sum of n1 and n2 is 2 or more,
Q₁ to Q₃ are each independently a single bond, O, S, C, C(R₂), C(R₂)(R₃), or a C₁-C₃₀ alkylene group unsubstituted or substituted with at least one R₁,
X₁ and X₂ are each independently O, S, Se, N(R₄), or C(R₄)(R₅),
R₁ to R₅ are each independently hydrogen, deuterium, —F, —Cl, —Br, —I, a hydroxyl group, a cyano group, a C₁-C₃₀ alkyl group, a C₂-C₃₀ alkenyl group, a C₂-C₃₀ alkynyl group, a C₁-C₃₀ alkoxy group, a C₁-C₃₀ alkylthio group, a C₅-C₆₀ carbocyclic group, a C₁-C₆₀ heterocyclic group, or —Si(Q₁₁)(Q₁₂)(Q₁₃), and
Q₁₁ to Q₁₃ are each independently hydrogen, deuterium, —F, —Cl, —Br, —I, a hydroxyl group, a cyano group, a C₁-C₃₀ alkyl group, a C₂-C₃₀ alkenyl group, a C₂-C₃₀ alkynyl group, a C₁-C₃₀ alkoxy group, or a C₁-C₃₀ alkylthio group.

According to an embodiment, L₁ and L₂ may be each independently a single bond, a methylene group, or an ethylene group.

According to an embodiment, m1 and m2 may be each independently 1 or 2.

According to an embodiment, Ar₁ and Ar₂ may be each independently a substituted or unsubstituted phenyl group.

According to an embodiment, a sum of n1 and n2 may be 4 to 6.

According to an embodiment, the low-temperature-active crosslinker may be a compound represented by Formula 2:

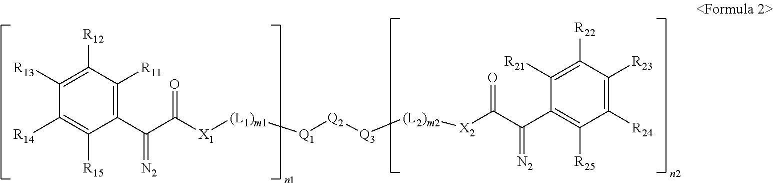

wherein, in the Formula 2,
descriptions of L₁, L₂, m1, m2, n1, n2, X₁, X₂ and Q₁ to Q₃ are the same as those described in this specification, and
descriptions of R₁₁ to R₁₅ and R₂₁ to R₂₅ are each independently identical to the description for R₁.

According to an embodiment, the crosslinkable compound may be at least one selected from Compounds 1 to 7 below:

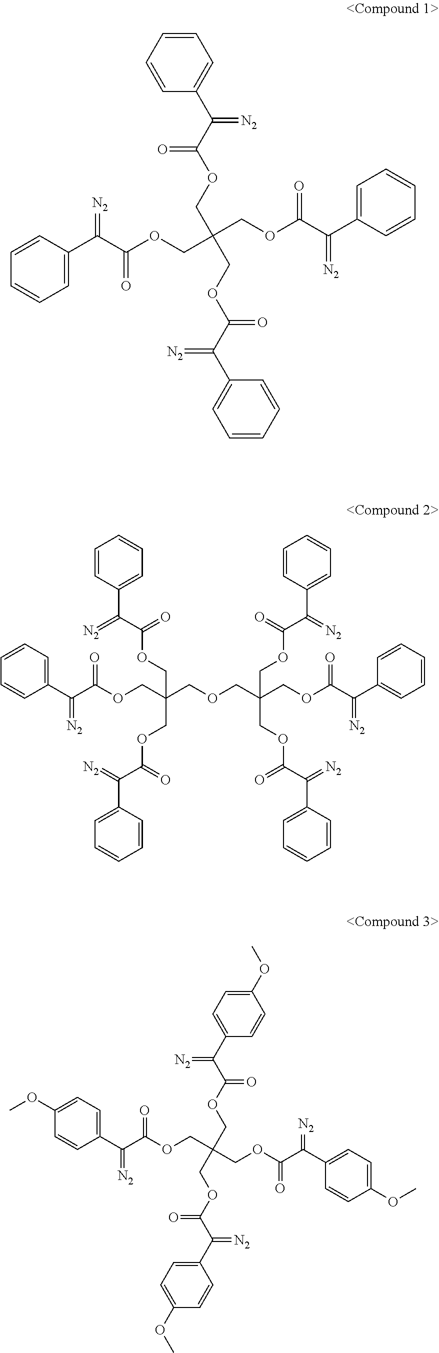

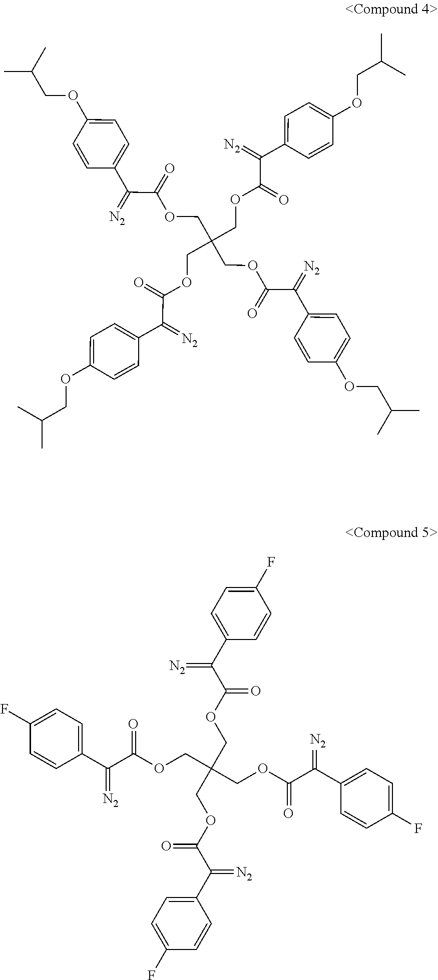

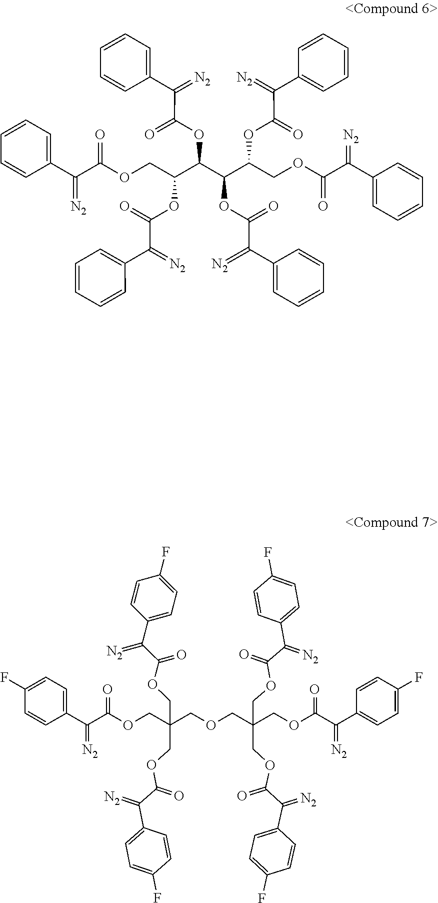

According to an embodiment, the low-temperature-active crosslinker may form a covalent bond with the colloidal particle.

For example, the colloidal particle may be a quantum dot, the quantum dot may include a semiconductor nanocrystal and an organic ligand on the surface of the semiconductor nanocrystal, and the low-temperature-active crosslinker may form a covalent bond (for example, a carbon-carbon bond) with the organic ligand.

According to an embodiment, the low-temperature-active crosslinker may be hydrophobic.

Typically, there are many cases that a photoresist includes a hydrophilic material including a large number of hydroxyl groups (—OHs). In these cases, since the low-temperature-active crosslinker satisfies the above-described characteristics, a pattern can be stably formed without a hydrophobic treatment process for a substrate when forming a photoresist pattern, and furthermore, there is an advantage in that a phenomenon of the optical and electrical properties of the colloidal particles being deteriorated by the hydrophobic treatment or the like can be prevented.

According to an embodiment, the colloidal particle ink composition may not include a hydrophobic treatment agent (for example, hexasiloxane).

According to an embodiment, the colloidal particle ink composition may not include a tackifier.

According to an embodiment, the colloidal particle ink composition may further include a solvent.

According to an embodiment, the solvent may be an organic solvent. For example, the solvent may include 1-octadecene (ODE), trioctylamine (TOA), trioctylphosphine (TOP), oleylamine, or any combination thereof.

According to an embodiment, the colloidal particle ink composition may be used in a solution process.

### [Method of Forming Colloidal Particle Pattern]

According to another aspect of the disclosure, a method of forming a colloidal particle pattern using the colloidal particle ink composition is provided.

In the method of forming a colloidal particle pattern using the colloidal particle ink composition, colloidal particles are crosslinked by the low-temperature-active crosslinker, and thus a crosslinking reaction may occur without heat treatment at a high-temperature (for example, a temperature exceeding 140° C.), thereby preventing a phenomenon of deterioration of luminescence characteristics or electrical characteristics due to damage of the colloidal particles in a solution process or a phenomenon of change or degradation of a morphology of the formed patterned thin film. In addition, since chemical crosslinking is formed in the colloidal particles, the colloidal particles have excellent chemical durability and/or solvent resistance, so that deterioration of the previously formed pattern can be prevented even when photopatterning is repeated as needed, thereby forming a high-quality multi-color colloidal particle pattern.

According to an embodiment, the method of forming a colloidal particle pattern may be a photoresist-guided indirect photopatterning method.

For example, the method of forming a colloidal particle pattern may be a method in which a thin film is formed on a preset photoresist pattern using the colloidal particle ink composition and the photoresist pattern is removed. That is, the photoresist pattern may serve as a guide as a reverse pattern of the colloidal particle pattern to be formed.

According to an embodiment, the method of forming a colloidal particle pattern includes: applying a first quantum dot ink composition including first colloidal particles and a first low-temperature-active crosslinker onto a first photoresist pattern;
annealing the applied first colloidal particle ink composition at a temperature of about 0° C. to about 130° C.; and
removing the first photoresist pattern to form a first colloidal particle pattern.

According to an embodiment, the process of applying the first colloidal particle ink composition may use a spin coating method, a spray coating method, a casting method, a drop casting method, a dipping method, a Langmuir-Blodgett (LB) method, an inkjet printing method, a screen printing method, a laser printing method, an imprinting method, a laser induced thermal imaging (LITI) method, or the like.

According to an embodiment, the process of annealing the applied first colloidal particle ink composition at a temperature of about 0° C. to about 130° C. may be performed for about 1 minute to about 60 minutes. For example, the annealing process may be performed for about 10 minutes to about 30 minutes.

According to an embodiment, the first photoresist pattern may have a thickness of about 0.5 nm to about 10 μm. For example, the thickness of the first photoresist pattern may be about 1 nm to about 1 μm, about 5 nm to about 100 nm, or about 10 nm to about 50 nm.

According to an embodiment, the first colloidal particle pattern may have a thickness of about 1 nm to about 50 nm. For example, the thickness of the first colloidal particle pattern may be about 10 nm to about 40 nm, or about 15 nm to about 25 nm.

According to an embodiment, a ratio of thickness of the first photoresist pattern to thickness of the first colloidal particle pattern may be about 1:1 to about 1:0.7.

As the thickness of the first colloidal particle pattern and the thickness of the first photoresist pattern satisfy the above-described ranges, the fidelity of the first colloidal particle pattern can be improved.

According to an embodiment, the method of forming a colloidal particle pattern may further include: reducing the thickness of the first photoresist pattern and/or the thickness of the first colloidal particle pattern by plasma etching.

The thickness of the first photoresist pattern and/or the thickness of the first colloidal particle pattern can be controlled by the plasma etching to satisfy the above-described thickness ratio, thereby improving the fidelity of the first colloidal particle pattern.

According to an embodiment, the plasma etching may use a reactive ion etching system. For example, the plasma etching may be performed using an Ar/O₂ mixed gas (about 10 sccm to about 80 sccm for Ar, about 1 sccm to about 30 sccm for O₂ gas) and a radio frequency (RF) power of about 10 W to about 100 W.

According to an embodiment, the method of forming a colloidal particle pattern may not include a process of reducing the thickness of the first photoresist pattern and/or the thickness the first colloidal particle pattern by plasma etching. For example, when the thickness of the first photoresist pattern is relatively small (for example, when the thickness of the first photoresist pattern is about 1 nm to about 1 μm, about 5 nm to about 100 nm, or about 10 nm to about 50 nm), the method of forming a colloidal particle pattern may not include a process of reducing the thickness of the first photoresist pattern and/or the thickness of the first colloidal particle pattern by plasma etching.

According to an embodiment, the process of removing the first photoresist pattern to form the first colloidal particle pattern may be performed using a strip solvent. For example, the strip solvent may be acetone.

According to an embodiment, the process of removing the first photoresist pattern to form the first colloidal particle pattern may further include a process of ultrasonicating the first photoresist pattern.

According to an embodiment, the method of forming a colloidal particle pattern may further include: forming a second photoresist pattern on the first colloidal particle pattern;
applying a second colloidal particle ink composition including second colloidal particles and a second low-temperature-active crosslinker onto the second photoresist pattern;
annealing the applied second colloidal particle ink composition at a temperature of about 0° C. to about 130° C.; and
removing the second photoresist pattern to form a second colloidal particle pattern.

According to an embodiment, the first colloidal particles and the second colloidal particles may exhibit different colors from each other.

In the method of forming a colloidal particle pattern using the colloidal particle ink composition, since chemical crosslinking is formed in the colloidal particles, the colloidal particles have excellent chemical durability and/or solvent resistance, so that even if patterning (for example, optical patterning, solution process patterning, or the like) is repeated as needed, deterioration of the previously formed pattern can be prevented, thereby forming a high-quality multi-color colloidal particle pattern.

According to an embodiment, the process of applying the second colloidal particle ink composition may use a spin coating method, a spray coating method, a casting method, a drop casting method, a dipping method, a Langmuir-Blodgett (LB) method, an inkjet printing method, a screen printing method, a laser printing method, an imprinting method, a laser induced thermal imaging (LITI) method, or the like.

According to an embodiment, the process of annealing the applied second colloidal particle ink composition at a temperature of about 0° C. to about 130° C. may be performed for about 1 minute to about 60 minutes. For example, the annealing process may be performed for about 10 minutes to about 30 minutes.

According to an embodiment, the second photoresist pattern may have a thickness of about 0.5 nm to about 50 nm. For example, the thickness of the second photoresist pattern may be about 5 nm to about 40 nm, or about 10 nm to about 25 nm.

According to an embodiment, the second colloidal particle pattern may have thickness of about 1 nm to about 50 nm. For example, the thickness of the second colloidal particle pattern may be about 10 nm to about 40 nm, or about 15 nm to about 25 nm.

According to an embodiment, the method of forming a colloidal particle pattern may further include a process of reducing the thickness of the second photoresist pattern and/or the thickness of the second colloidal particle pattern by plasma etching.

According to an embodiment, the process of removing the second photoresist pattern to form the second colloidal particle pattern may be performed using a strip solvent. For example, the strip solvent may be acetone.

According to an embodiment, the process of removing the second photoresist pattern to form the second colloidal particle pattern may further include a process of ultrasonicating the second photoresist pattern.

According to an embodiment, the method of forming a colloidal particle pattern may further include: forming a third photoresist pattern on the second colloidal particle pattern;
applying a third colloidal particle ink composition including third colloidal particles and a third low-temperature-active crosslinker onto the third photoresist pattern;
annealing the applied third colloidal particle ink composition at a temperature of about 0° C. to about 130° C.; and
removing the third photoresist pattern to form a third colloidal particle pattern.

According to an embodiment, the first colloidal particles and the third colloidal particles may exhibit different colors from each other.

According to an embodiment, the second colloidal particles and the third colloidal particles may exhibit different colors from each other.

According to an embodiment, the process of applying the third colloidal particle ink composition may use a spin coating method, a spray coating method, a casting method, a drop casting method, a dipping method, a Langmuir-Blodgett (LB) method, an inkjet printing method, a screen printing method, a laser printing method, an imprinting method, a laser induced thermal imaging (LITI) method, or the like.

According to an embodiment, the process of annealing the applied third colloidal particle ink composition at a temperature of about 0° C. to about 130° C. may be performed for about 1 minute to about 60 minutes. For example, the annealing process may be performed for about 10 minutes to about 30 minutes.

According to an embodiment, the third photoresist pattern may have a thickness of about 0.5 nm to about 50 nm. For example, the thickness of the third photoresist pattern may be about 5 nm to about 40 nm, or about 10 nm to about 25 nm.

According to an embodiment, the third colloidal particle pattern may have a thickness of about 1 nm to about 50 nm. For example, the thickness of the third colloidal particle pattern may be about 10 nm to about 40 nm, or about 15 nm to about 25 nm.

According to an embodiment, the method of forming a colloidal particle pattern may further include a process of reducing the thickness of the third photoresist pattern or the thickness of the third colloidal particle pattern by plasma etching.

According to an embodiment, the process of removing the third photoresist pattern to form the third colloidal particle pattern may be performed using a strip solvent. For example, the strip solvent may be acetone.

According to an embodiment, the process of removing the third photoresist pattern to form the third colloidal particle pattern may further include a process of ultrasonicating the third photoresist pattern.

### [Colloidal Particle Patterned Film]

According to another aspect of the present disclosure, a colloidal particle patterned film formed using the colloidal particle ink composition is provided.

In the colloidal particle patterned film formed using the colloidal particle ink composition, colloidal particles are crosslinked by the low-temperature-active crosslinker, and thus a crosslinking reaction may occur without heat treatment at a high-temperature (for example, a temperature exceeding 140° C.), thereby preventing a phenomenon of deterioration of luminescence characteristics or electrical characteristics due to damage of the colloidal particles in a solution process or a phenomenon of change or degradation of a morphology of the formed patterned thin film. In addition, since chemical crosslinking is formed in the colloidal particles, the colloidal particles have excellent chemical durability and/or solvent resistance, so that deterioration of the previously formed pattern can be prevented even when photopatterning is repeated as needed, thereby forming a high-quality multi-color colloidal particle pattern.

A colloidal particle patterned film according to an embodiment may be manufactured according to the above-described method of forming the colloidal particle pattern.

According to an embodiment, the colloidal particle patterned film may include: a substrate; and a colloidal particle pattern formed on the substrate.

According to an embodiment, the substrate may be selected in consideration of mechanical strength, thermal stability, surface smoothness, ease of handling, and waterproofness, and for example, a silicon wafer, a glass substrate, a plastic film such as polyethersulfone, polyacrylate, polyetherimide, polyimide, polyethylene naphthalate, or polyethylene terephthalate, or an organic substrate coated with this plastic film may be used.

According to an embodiment, the substrate may have a single-layered or multi-layered structure.

For example, the substrate may have a single-layered structure including a resin. For another example, the substrate may have a multi-layered structure including two or more layers each including two or more different types of resin. For another example, the substrate may have a multi-layered structure including a resin-containing layer and a functional layer, and the functional layer may be, for example, an adhesive layer, an anti-corrosion layer, an anti-reflection layer, a hard coating layer, or a combination thereof.

According to an embodiment, the colloidal particle pattern may have a thickness of about 1 nm to about 200 nm. For example, the thickness of the colloidal particle pattern may be about 5 nm to about 100 nm, about 10 nm to about 40 nm, or about 15 nm to about 25 nm.

### [Electronic Device]

According to another aspect of the present disclosure, an electronic device including the colloidal particle pattern is provided.

According to an embodiment, the electronic device may a colloidal particle light-emitting device, the colloidal particle light-emitting device may include a first electrode, a second electrode facing the first electrode, and an intermediate layer between the first electrode and the second electrode and including a light-emitting layer, and the light-emitting layer may include the colloidal particle pattern.

According to an embodiment, the electronic device may be a thin film transistor (TFT), an electrochromic device (EC), a light emitting diode (LED), a solar cell, or a photodiode.

According to an embodiment, the electronic device may be a light-emitting device.

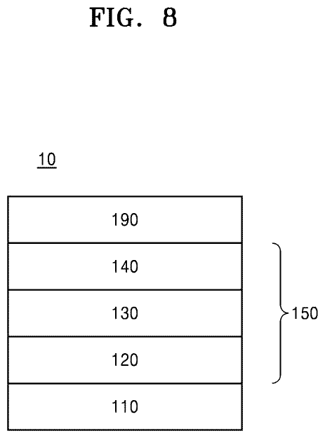

FIG. 8 schematically illustrates an example of a light-emitting device according to an aspect of the present disclosure. The light-emitting device 10 includes a first electrode 110, an intermediate layer 150, and a second electrode 190, and the intermediate layer 150 includes a hole transport region 120 and a light-emitting layer 130.

A substrate (not shown) may be additionally placed beneath the first electrode 110 and/or on the second electrode 190. As the substrate, a glass substrate or plastic substrate having excellent mechanical strength, thermal stability, transparency, surface smoothness, ease of handling, and waterproofing may be used.

The first electrode 110 may be formed by providing a first electrode material on the substrate using a deposition method or a sputtering method.

The first electrode 110 may be a transmissive electrode. In order to form the first electrode 110, which is a transmissive electrode, the material for the first electrode may be selected from, but is not limited to, indium tin oxide (ITO), indium zinc oxide (IZO), tin oxide (SnO₂), zinc oxide (ZnO), aluminum-doped zinc oxide (AZO), gallium-doped zinc oxide (GZO), antimony tin oxide (ATO), fluorine tin oxide (FTO), silver nanoparticles, silver nanowires, carbon nanotubes (CNTs), and any combination thereof. Alternatively, in order to form the first electrode 110, which is a semi-transmissive electrode or a reflective electrode, the material for the first electrode may be selected from magnesium (Mg), silver (Ag), aluminum (Al), aluminum-lithium (Al—Li), calcium (Ca), magnesium-indium (Mg—In), magnesium-silver (Mg—Ag), and any combination thereof, but the disclosure is not limited thereto.

A hole transport region 120 may be placed on the first electrode 110.

The hole transport region may include a hole injection layer, a hole transport layer, a light-emitting auxiliary layer, an electron blocking layer, or a combination thereof.

The hole transport layer may include a hole-transporting compound.

For example, the hole-transporting compound may be a hole-transporting polymer compound such as TFB (poly[(9,9-dioctylfluorenyl-2,7-diyl)-co-(4,4′-(N-(4-sec-butylphenyl)diphenylamine)]) or PTAA (poly[bis(4-phenyl)(2,4,6-trimethylphenyl)amine]).

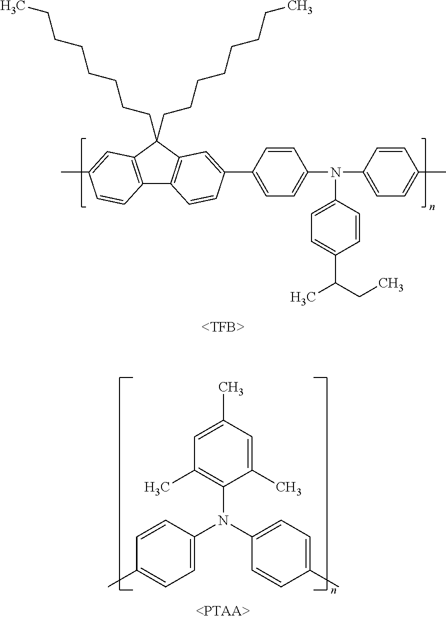

For another example, the hole-transporting compound may be a hole-transporting low-molecular compound that does not contain a π-electron-deficient nitrogen ring. Examples of the hole-transporting low-molecular compounds include carbazole-containing compounds, amine compounds, and the like.

A light-emitting layer 130 may be placed on the hole transport region 120.

The light-emitting layer 130 may include the above-described colloidal particle pattern formed using the colloidal particle ink composition.

The thickness of the light-emitting layer 130 may be about 100 Å to about 1,000 Å, for example, about 200 Å to about 600 Å. When the thickness of the light-emitting layer 130 satisfies the above-described ranges, excellent light-emitting characteristics can be exhibited without a substantial increase in driving voltage.

An electron transport region 140 may be placed on the light-emitting layer 130.

The electron transport region 140 may include a buffer layer, a hole blocking layer, an electron control layer, an electron transport layer, an electron injection layer, or any combination thereof.

For example, the electron transport region 140 may have a laminate structure such as an electron transport layer/electron injection layer, a hole blocking layer/electron transport layer/electron injection layer, an electron control layer/electron transport layer/electron injection layer, or a buffer layer/electron transport layer/electron injection layer.

The electron transport region 140 may include an electron-transporting compound.

For example, the electron-transporting compound may be a metal-free compound containing at least one π-electron-deficient nitrogen ring, BCP (2,9-Dimethyl-4,7-diphenyl-1,10-phenanthroline), Bphen (4,7-Diphenyl-1,10-phenanthroline), Alq₃, BAlq, TAZ (3-(Biphenyl-4-yl)-5-(4-tert-butylphenyl)-4-phenyl-4H-1,2,4-triazole), NTAZ, or TPBi.

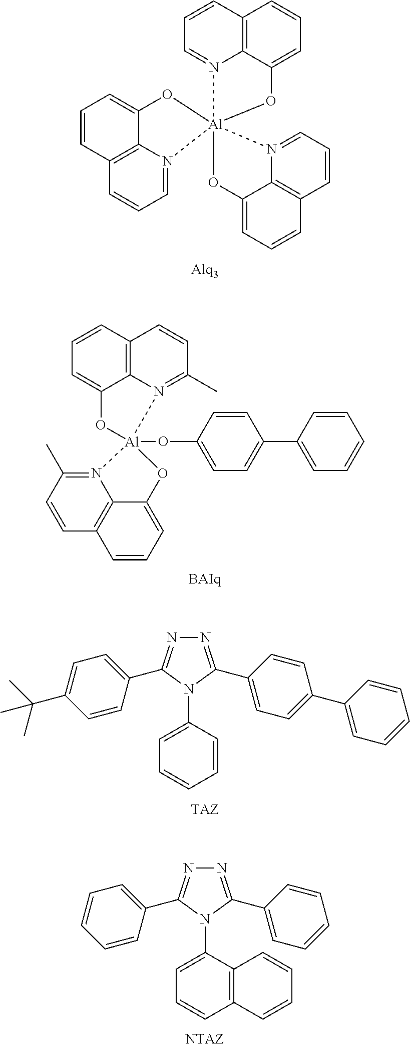

The “π electron-deficient nitrogen-containing ring” refers to a C₁-C₆₀ heterocyclic group having at least one *—N═*′ moiety as a ring-forming moiety.

For example, the “π electron-deficient nitrogen-containing ring” may be i) a 5- to 7-membered heteromonocyclic group having at least one *—N═*′ moiety, ii) a heteropolycyclic group in which two or more of the 5- to 7-membered heteromonocyclic groups having at least one *—N═*′ moiety are condensed with each other, or iii) a heteropolycyclic group in which at least one of the 5- to 7-membered heteromonocyclic groups having at least one *—N═*′ moiety and at least one C₅-C₆₀ carbocyclic group are condensed with each other.

Examples of the π electron-deficient nitrogen-containing ring may include imidazole, pyrazole, thiazole, isothiazole, oxazole, isoxazole, pyridine, pyrazine, pyrimidine, pyridazine, indazole, purine, quinoline, isoquinoline, benzoquinoline, phthalazine, naphthyridine, quinoxaline, quinazoline, cinnoline, phenanthridine, acridine, phenanthroline, phenazine, benzimidazole, isobenzothiazole, benzoxazole, isobenzoxazole, triazole, tetrazole, oxadiazole, triazine, thiadiazole, imidazopyridine, imidazopyrimidine, azacarbazole, and the like.

The electron transport region may further include a metal or a metal complex in addition to the above-described electron-transporting compound. For example, the electron transport region may further include oxides and halides (for example, fluorides, chlorides, bromides, iodides, and the like) of alkali metals, alkaline earth metals and rare earth metals, alkali metal complexes, alkaline earth metal complexes, or combinations thereof. For example, the electron transport region may further include LiQ. For example, the electron transport region may further include molybdenum oxide (MoOₓ).

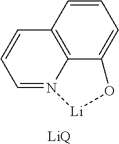

The thickness of the electron transport region may be about 100 Å to about 2,000 Å, for example, about 150 Å to about 1,000 Å. When the thickness of the electron transport region satisfies the above-described ranges, satisfactory electron-transporting characteristics can be obtained without a substantial increase in driving voltage.

A second electrode 190 is placed on the electron transport region 140. The second electrode 190 may be a cathode, which is an electron injection electrode.

As the material of the second electrode 190, a metal, alloy, electrically conductive compound or a combination thereof having a low work function may be used.

The second electrode 190 may include at least one selected from lithium (Li), silver (Ag), magnesium (Mg), aluminum (Al), aluminum-lithium (Al—Li), calcium (Ca), magnesium-indium (Mg—In), magnesium-silver (Mg—Ag), silver-magnesium (Ag—Mg), ITO, and IZO, but the disclosure is not limited thereto. The second electrode 190 may be a transmissive electrode, a transflective electrode, or a reflective electrode.

The second electrode 190 may have a single-layered structure or a multi-layered structure having multiple layers.

Each layer of the light-emitting device may be formed using various methods, such as vacuum deposition, spin coating, casting, Langmuir-Blodgett (LB) method, inkjet printing, laser printing, and laser induced thermal imaging (LITI).

According to an embodiment, the electronic device may be a flexible electronic device.

According to an embodiment, the electronic device may be a stretchable electronic device.

### Definition of Substituent

The term “C₅-C₆₀ carbocyclic group” in this specification refers to a monocyclic or polycyclic group having 5 to 60 carbon atoms and containing only carbon as a ring-forming atom. The C₅-C₆₀ carbocyclic group may be an aromatic carbocyclic group or a non-aromatic carbocyclic group. The C₅-C₆₀ carbocyclic group may be a ring such as benzene, a monovalent group such as a phenyl group, or a divalent group such as a phenylene group. Alternatively, depending on the number of substituents linked to the C₅-C₆₀ carbocyclic group, the C₅-C₆₀ carbocyclic group may be modified in various ways, such as being a trivalent group or a tetravalent group.

The C₁-C₆₀ heterocyclic group in this specification refers to a group having the same structure as the C₅-C₆₀ carbocyclic group, but including, as a ring-forming atom, at least one heteroatom selected from N, O, Si, P, and S, in addition to carbon (carbon number may be 1 to 60).

The C₁-C₃₀ alkyl group in this specification refers to a linear or branched aliphatic hydrocarbon group having 1 to 30 carbon atoms, and specific examples thereof include a methyl group, an ethyl group, a propyl group, an isobutyl group, a sec-butyl group, a ter-butyl group, a pentyl group, an iso-amyl group, a hexyl group, a heptyl group, an n-octyl group, a 2-ethylhexyl group, and the like.

The C₂-C₃₀ alkenyl group in this specification refers to a hydrocarbon group including one or more carbon double bonds at the middle or terminal of the C₂-C₃₀ alkyl group, and specific examples thereof include an ethenyl group, a propenyl group, a butenyl group, and the like.

The C₂-C₃₀ alkynyl group in this specification refers to a hydrocarbon group including one or more carbon triple bonds at the middle or terminal of the C₂-C₃₀ alkyl group, and specific examples thereof include an ethynyl group, a propynyl group, and the like.

The C₁-C₃₀ alkoxy group in this specification refers to a monovalent group having a formula of —OA₁₀₁ (wherein, A₁₀₁ is the C₁-C₃₀ alkyl group), and specific examples thereof include a methoxy group, an ethoxy group, an isopropyloxy group, and the like.

The C₁-C₃₀ alkylthio group in this specification refers to a monovalent group having a formula of —SA₁₀₁ (wherein, A₁₀₁ is the C₁-C₃₀ alkyl group), and specific examples thereof include a methylthio group, an ethylthio group, an isopropylthio group, and the like.

In this specification, * and *′ refer to a bonding site with an adjacent atom in the formula.

Hereinafter, the disclosure will be described in more detail through Examples. These Examples are intended to describe the disclosure more specifically, and the scope of the disclosure is not limited by the Examples.

### EXAMPLES

### Synthesis Example 1: Preparation of Compounds 1 to 7

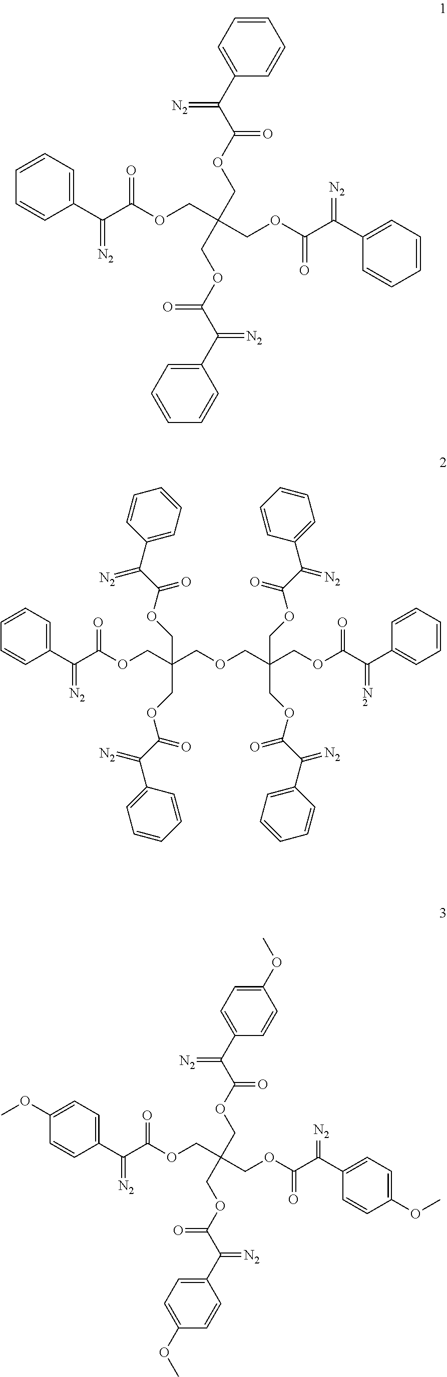

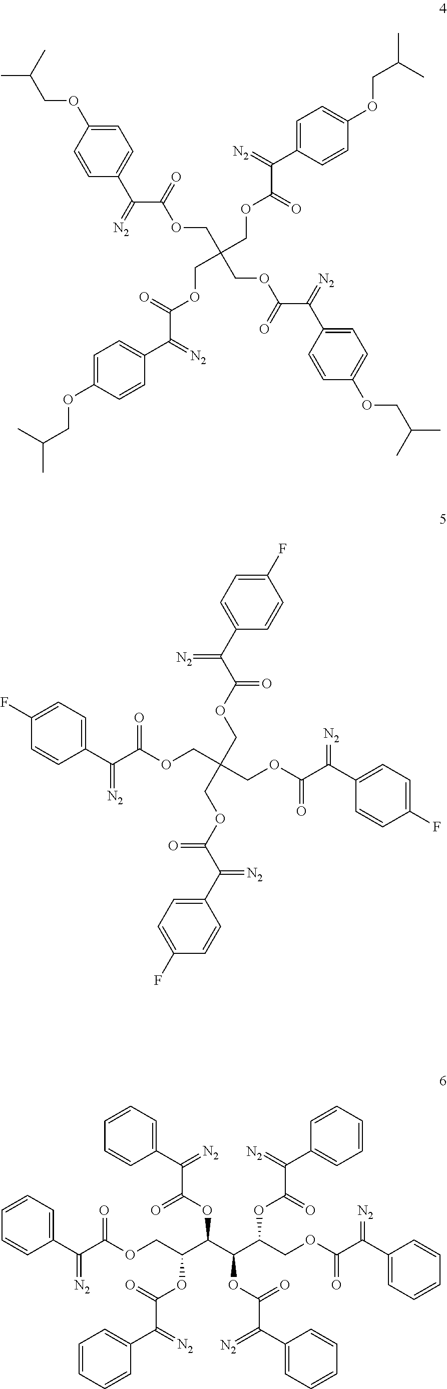

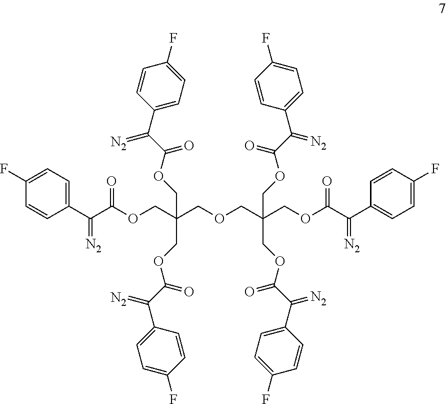

### (1) Preparation of Crosslinkable Compound 1

A mixed solution of phenyl acetyl chloride (1020 mg, 6.60 mmol) and pentaerythritol (150 mg, 1.10 mmol) was stirred at 140° C. for 18 hours under an argon atmosphere. Then, the mixed solution was cooled to room temperature and extracted using dichloromethane and distilled water to obtain an organic layer. The organic layer was dried with MgSO₄, filtered, and concentrated using a rotary evaporator. The material was purified by silica gel column chromatography (developing solvent=ethyl acetate:hexane=1:4 by volume) to obtain a white solid (483 mg, 72%). ¹H-NMR (400 MHz, CDCl₃) δ: 7.29-7.15 (m, 20H), 3.87 (s, 8H), 3.51 (s, 8H).

Under an argon atmosphere, the white solid (400 mg, 0.66 mmol) obtained in the above process and p-ABSA (789 mg, 3.28 mmol) were dissolved in anhydrous THE (10 mL) and stirred for 10 minutes to obtain a solution. DBU (670 mg, 4.40 mmol) was slowly added dropwise to the solution and stirred at room temperature for 12 hours. Next, the solution was extracted using dichloromethane and distilled water to obtain an organic layer. The organic layer was dried with MgSO₄, filtered, and concentrated using a rotary evaporator. The material was purified by silica gel column chromatography (developing solvent=ethyl acetate:hexane=1:5 by volume). The obtained material was recrystallized using chloroform and methanol to obtain crosslinkable compound 1 as an orange solid (433 mg, 92%). ¹H-NMR (400 MHz, CDCl₃) δ: 7.43-7.34 (m, 16H), 7.21-7.16 (t, J=8.0 Hz, 4H), 4.41 (s, 8H).

### (2) Preparation of Crosslinkable Compound 2

A mixed solution of phenyl acetyl chloride (2193 mg, 14.18 mmol) and dipentaerythritol (500 mg, 1.97 mmol) was stirred at 120° C. for 18 hours under an argon atmosphere. Then, the mixed solution was cooled to room temperature and extracted using dichloromethane and distilled water to obtain an organic layer. The organic layer was dried with MgSO₄, filtered, and concentrated using a rotary evaporator. The material was purified by silica gel column chromatography (developing solvent=ethyl acetate:hexane=1:3 by volume) to obtain a sticky yellow solid (1506 mg, 80%). ¹H-NMR (400 MHz, CDCl₃) δ: 7.31-7.18 (m, 30H), 3.87 (s, 12H), 3.53 (s, 12H), 2.87 (s, 4H).

Under an argon atmosphere, the sticky yellow liquid (1000 mg, 1.04 mmol) obtained in the above process and p-ABSA (1795 mg, 7.47 mmol) were dissolved in anhydrous acetonitrile (20 mL) and stirred for 10 minutes. DBU (1580 mg, 10.38 mmol) was slowly added dropwise to the solution and stirred at room temperature for 24 hours. Next, the solution was extracted using dichloromethane and distilled water to obtain an organic layer. The organic layer was dried with MgSO₄, filtered, concentrated using a rotary evaporator, and then the material was purified using silica gel column chromatography (developing solvent=dichloromethane). The obtained material was recrystallized using chloroform and methanol to obtain crosslinkable compound 2 as an orange solid (577 mg, 49%). ¹H-NMR (400 MHz, CDCl₃) δ: 7.39-7.33 (m, 24H), 7.17-7.13 (t, 6H), 4.37 (s, 12H).

### (3) Preparation of Crosslinkable Compound 3

A mixed solution of 4-methoxyphenyl acetyl chloride (1605 mg, 11.02 mmol) and pentaerythritol (300 mg, 2.203 mmol) was stirred at 120° C. for 12 hours under an argon atmosphere. Then, the mixed solution was cooled to room temperature and extracted using dichloromethane and distilled water to obtain an organic layer. The organic layer was dried with MgSO₄, filtered, and concentrated using a rotary evaporator. The material was purified by silica gel column chromatography (developing solvent=ethyl acetate:hexane=1:1 by volume) to obtain a white solid (1498 mg, 93%). ¹H-NMR (400 MHz, CDCl₃) δ: 7.09 (d, J=8 Hz, 8H), 6.82 (d, J=8 Hz, 8H), 3.91 (s, 8H), 3.77 (s, 12H), 3.46 (s, 8H).

Under an argon atmosphere, the white liquid (300 mg, 0.412 mmol) obtained in the above process and p-ABSA (611 mg, 2.470 mmol) were dissolved in anhydrous acetonitrile (7 mL) and stirred for 10 minutes. DBU (376 mg, 2.470 mmol) was slowly added dropwise to the solution and stirred at room temperature for 24 hours. Next, the solution was extracted using dichloromethane and distilled water to obtain an organic layer. The organic layer was dried with MgSO₄, filtered, and concentrated using a rotary evaporator. The material was purified by silica gel column chromatography (developing solvent=ethyl acetate:dichloromethane=1:20 by volume). The obtained material was recrystallized using chloroform and methanol to obtain crosslinkable compound 3 as an orange solid (433 mg, 92%). ¹H-NMR (400 MHz, CDCl₃) δ: 7.31 (d, J=8 Hz, 8H), 6.91 (d, J=8 Hz, 8H), 4.36 (s, 8H), 3.80 (s, 12H).

### (4) Preparation of Crosslinkable Compound 4

A mixed solution of 4-methoxyphenyl acetyl chloride (1605 mg, 11.02 mmol) and pentaerythritol (300 mg, 2.203 mmol) was stirred at 120° C. for 12 hours under an argon atmosphere. Then, the mixed solution was cooled to room temperature and extracted using dichloromethane and distilled water to obtain an organic layer. The organic layer was dried with MgSO₄, filtered, and concentrated using a rotary evaporator. The material was purified by silica gel column chromatography (developing solvent=ethyl acetate:hexane=1:1 by volume) to obtain a white solid (1498 mg, 93%). ¹H-NMR (400 MHz, CDCl₃) δ: 7.09 (d, J=8 Hz, 8H), 6.82 (d, J=8 Hz, 8H), 3.91 (s, 8H), 3.77 (s, 12H), 3.46 (s, 8H).

Under an argon atmosphere, the white liquid (1000 mg, 1.372 mmol) obtained in the above process and p-ABSA (611 mg, 2.470 mmol) were dissolved in anhydrous dichloromethane (40 mL) and stirred at −78° C. for 1 hour. Then, a BBr₃ solution (1 M in DCM, 6.2 mL, 6.174 mmol) was slowly added dropwise to the solution and stirred at 0° C. for 7 hours. A saturated aqueous NaHCO₃ solution was slowly added dropwise to the resulting solution to terminate a reaction, and extraction was performed using ethyl acetate to obtain an organic layer. The organic layer was dried with MgSO₄, filtered, and concentrated using a rotary evaporator. The obtained material was formed into a precipitate by hexane to obtain a white solid (551 mg, 60%). ¹H-NMR (400 MHz, DMSO-d₆) δ: 8.33 (s, 4H), 6.98 (d, J=8 Hz, 8H), 6.67 (d, J=8 Hz, 8H), 3.94 (s, 8H), 3.46 (s, 8H)

Under an argon atmosphere, the white solid (100 mg, 0.149 mmol) obtained in the above process, 1-bromo-2-methyl-propane (611 mg, 2.470 mmol), and K₂CO₃ (144 mg, 1.043 mmol) were dissolved in anhydrous DMF (7 mL) and stirred at 110° C. for 24 hours. The mixed solution was cooled to room temperature and extracted using dichloromethane and distilled water to obtain an organic layer. The organic layer was dried over MgSO₄, filtered, and concentrated using a rotary evaporator. The material was purified by silica gel column chromatography (developing solvent=ethyl acetate:hexane=1:3 by volume) to obtain a sticky liquid product (73 mg, 54%). ¹H-NMR (400 MHz, CDCl₃) δ: 7.07 (d, J=8 Hz, 8H), 6.81 (d, J=8 Hz, 8H), 3.93 (s, 8H), 3.67 (d, J=8 Hz, 8H), 3.45 (s, 12H), 2.09-2.02 (m, 4H), 1.01 (d, J=4 Hz, 24H).

Under an argon atmosphere, the liquid product (73 mg, 0.081 mmol) obtained in the above process and p-ABSA (74 mg, 0.486 mmol) were dissolved in anhydrous acetonitrile (5 mL) and stirred for 10 minutes. DBU (117 mg, 0.486 mmol) was slowly added dropwise to the solution and stirred at room temperature for 24 hours. Next, the solution was extracted using dichloromethane and distilled water to obtain an organic layer. The organic layer was dried with MgSO₄, filtered, and concentrated using a rotary evaporator. The material was purified by silica gel column chromatography (developing solvent=ethyl acetate:hexane=1:5 by volume). The obtained material was recrystallized using dichloromethane and methanol to obtain crosslinkable compound 4 as an orange solid (9 mg, 11%). ¹H-NMR (400 MHz, CDCl₃) δ: 7.29 (d, J=8 Hz, 8H), 6.90 (d, J=8 Hz, 8H), 4.34 (s, 8H), 3.70 (d, J=4 Hz, 8H), 2.10-2.03 (m, 4H), 1.02 (d, J=4 Hz, 24H).

### (5) Preparation of Crosslinkable Compound 5

A mixed solution of 4-fluorophenyl acetyl chloride (1267 mg, 7.345 mmol) and pentaerythritol (200 mg, 1.469 mmol) was stirred at 140° C. for 18 hours. The mixed solution was cooled to room temperature and then extracted using dichloromethane and distilled water to obtain an organic layer. The organic layer was dried with MgSO₄, filtered, and concentrated using a rotary evaporator. The material was purified by silica gel column chromatography (developing solvent=ethyl acetate:hexane=1:2 by volume) to obtain a white solid (806 mg, 81%). ¹H-NMR (400 MHz, CDCl₃) δ: 7.14 (dd, J=8 Hz, 4 Hz, 8H), 6.99 (t, J=8 Hz, 8H), 3.93 (s, 8H), 3.51 (s, 8H).

Under an argon atmosphere, the white solid (400 mg, 0.588 mmol) obtained in the above process and p-ABSA (1019 mg, 4.114 mmol) were dissolved in anhydrous acetonitrile (10 mL) and stirred for 10 minutes. Then, DBU (626 mg, 2.470 mmol) was slowly added dropwise to the solution and stirred at room temperature for 24 hours. Then, the solution was extracted using dichloromethane and distilled water to obtain an organic layer. The organic layer was dried with MgSO₄, filtered, and concentrated using a rotary evaporator. The material was purified by silica gel column chromatography (developing solvent=dichloromethane). The obtained material was recrystallized using chloroform and methanol to obtain crosslinkable compound 5 as an orange solid (78 mg, 17%). ¹H-NMR (400 MHz, CDCl₃) δ: 7.38 (t, J=8 Hz, 8H), 7.08 (t, J=8 Hz, 8H), 4.38 (s, 8H).

### (6) Preparation of Crosslinkable Compound 6

A mixed solution of phenyl acetyl chloride (7636 mg, 49.40 mmol) and D-mannitol (1000 mg, 5.489 mmol) was stirred at 130° C. for 24 hours under an argon atmosphere. The mixed solution was cooled to room temperature and then extracted using dichloromethane and distilled water to obtain an organic layer. The organic layer was dried with MgSO₄, filtered, and concentrated using a rotary evaporator. The material was purified by silica gel column chromatography (developing solvent=ethyl acetate:hexane=1:5 by volume) to obtain a light yellow liquid (1177 mg, 24%). ¹H-NMR (400 MHz, CDCl₃) δ: 7.32-7.19 (m, 30H), 5.46 (d, J=8 Hz, 2H), 5.11-5.07 (m, 2H), 4.20 (s, 1H), 4.19 (s, 1H), 3.88 (d, J=4 Hz, 1H), 3.85 (d, J=4 Hz, 1H), 3.60 (d, J=4 Hz, 4H), 3.54 (d, J=4 Hz, 4H), 3.50 (s, 4H).

Under an argon atmosphere, the light yellow liquid (1157 mg, 1.299 mmol) obtained in the above process and p-ABSA (2808 mg, 11.69 mmol) were dissolved in anhydrous acetonitrile (50 mL) and stirred for 10 minutes. Then, DBU (1780 mg, 11.69 mmol) was slowly added dropwise to the solution and stirred at room temperature for 24 hours. Then, the solution was extracted using dichloromethane and distilled water to obtain an organic layer. The organic layer was dried with MgSO₄, filtered, and concentrated using a rotary evaporator. The material was purified by silica gel column chromatography (developing solvent=dichloromethane). The obtained material was recrystallized using chloroform and methanol to obtain crosslinkable compound 6 as a yellow solid (279 mg, 21%). ¹H-NMR (400 MHz, CDCl₃) δ: 7.40-7.14 (m, 30H), 5.81 (d, J=8 Hz, 2H), 5.49 (m, 2H), 4.70 (d, J=12 Hz, 2H), 4.35 (dd, J=12 Hz, 4 Hz, 2H).

### (7) Preparation of Crosslinkable Compound 7

A mixed solution of 4-fluorophenyl acetyl chloride (1010 mg, 5.852 mmol) and dipentaerythritol (250 mg, 0.836 mmol) was stirred at 120° C. for 18 hours. The mixed solution was cooled to room temperature and then extracted using dichloromethane and distilled water to obtain an organic layer. The organic layer was dried with MgSO₄, filtered, and concentrated using a rotary evaporator. The material was purified by silica gel column chromatography (developing solvent=ethyl acetate:hexane=1:2 by volume) to obtain a white solid (710 mg, 79%). ¹H-NMR (400 MHz, CDCl₃) δ: 7.17 (t, J=4 Hz, 4 Hz, 12H), 6.99 (t, J=4 Hz, 12H), 3.92 (s, 12H), 3.52 (s, 12H), 2.94 (s, 4H).

Under an argon atmosphere, the white solid (400 mg, 0.374 mmol) obtained in the above process and p-ABSA (897 mg, 3.735 mmol) were dissolved in anhydrous acetonitrile (10 mL) and stirred for 10 minutes. Then, DBU (568 mg, 3.735 mmol) was slowly added dropwise to the solution and stirred at room temperature for 24 hours. Then, the solution was extracted using dichloromethane and distilled water to obtain an organic layer. The organic layer was dried with MgSO₄, filtered, and concentrated using a rotary evaporator. The material was purified by silica gel column chromatography (developing solvent=chloroform:hexane=30:1 by volume). The obtained material was recrystallized using chloroform and hexane to obtain crosslinkable compound 7 as an orange solid (160 mg, 35%). ¹H-NMR (400 MHz, CDCl₃) δ: 7.34 (t, J=4 Hz, 12H), 7.03 (t, J=8 Hz, 12H), 4.34 (s, 12H), 3.46 (s, 4H).

### Preparation Example 1: Preparation of Quantum Dot Ink Composition

### (1) Preparation of Red Quantum Dot Ink Composition

Zinc oleate (0.5 M, Zn(OA)₂) was prepared by heating 20 mmol of Zn(OAc)₂ with 12 mL of OA at 150° C. for 1 hour then diluting them with ODE, and then diluted with ODE to make zinc oleate to a total volume of 40 mL. Trioctylphosphine selenium (1 M, TOPSe) and trioctylphosphine sulfur (1 M, TOPS) were prepared by stirring 1 mmol of Se or S with 1 ml of TOP overnight at room temperature.

In the case of red-emitting CdSe/ZnSe/ZnS quantum dots (r=3.0 nm, I=5.0 nm, h=2.0 nm), 0.3 mmol of CdO, 1 mmol of OA, and 6 ml of ODE were introduced into a three-necked flask and heated to 300° C. under inert conditions to form a transparent Cd(OA)₂ solution. Then, 0.5 ml of TOPSe (1 M) was rapidly injected into a reaction flask. After 3 minutes, 5 ml of a Cd, Se stock solution was injected into ODE to grow a CdSe core. Then, to grow a ZnSe shell, 20 ml of Zn(OA)₂ (0.5 M) and 7 ml of TOPSe were sequentially added. Finally, to grow the ZnS shell, 10 ml of Zn(OA)₂ (0.5 M) and 5 ml of TOPS were added. The synthesized red-emitting CdSe/ZnSe/ZnS quantum dots were purified five times by a precipitation/redispersion (ethanol/toluene) method.

Compound 1 was added to a red light-emitting CdSe/ZnSe/ZnS quantum dot solution dissolved in toluene (55 mg/mL) by 5 wt % relative to the quantum dots to prepare a red quantum dot ink composition.

### (2) Synthesis of Green Quantum Dot Ink Composition

Green light-emitting InP/ZnSeS quantum dots were purchased from Uniam Inc.

Compound 1 was added to a green light-emitting InP/ZnSeS quatum dot solution dissolved in toluene (55 mg/mL) by 5 wt % relative to the quantum dots to prepare a green quantum dot ink composition.

### (3) Synthesis of Blue Quantum Dot Ink Composition

A stock solution of Zn(OA)₂ (0.5 M) was prepared in ODE as a cation precursor. TOPSe (2 M), trioctylphosphine telluride (0.05 M, TOPTe), and diphenylphosphine selenide (0.2 M, DPPSe) were prepared as anion precursors. For the preparation of Zn(OA)₂, 50 mmol of Zn(Ac)₂ and 100 mmol of OA were introduced into a flask, degassed at 130° C. for 6 hours, and then refilled with N2 gas and diluted with ODE to a concentration of 0.5 M. For the preparation of TOPSe, 100 mmol of Se powder was mixed with 50 mL of TOP at 160° C. for 5 hours under an inert condition. TOPTe was prepared in the same manner.

4 mmol of Se powder was reacted with 2 mL of DPP at 200° C. under an inert condition until the reaction was completed, and then diluted to 0.2 M concentration with toluene at RT to prepare DPPSe.

ZnSeTe/ZnSe/ZnS quantum dots (r=1.8 nm, I=1.8 nm, h=0.6 nm) were synthesized by a slightly modified previously reported method (1). 1.2 mL of Zn(OA)₂ (0.5 M) and 10 mL of ODE were introduced into a three-necked round flask, and then stirred and degassed at 110° C. The flask was degassed for 1 hour to completely remove water and oxygen, and was then refilled with N2 gas. Then, a mixture of 1.43 mL of DPPSe (0.2 M) and 0.3 mL of TOPTe (0.05 M) was injected to synthesize a ZnSe_{0.95}Te_{0.05} core at 230° C., and maintained for 30 minutes. Then, the temperature was increased to 300° C. for 15 minutes to allow the ZnSe_{0.95}Te_{0.05} core (r=1.8 nm) to grow completely. To further grow the ZnSe shell on the core, 2 mL/3.4 mL/5 mL of Zn(OA)₂ (0.5 M) and 0.25 mL /0.425 mL/0.625 mL of TOPSe (2 M) were sequentially injected at 300° C. 10 mL of Zn(OA)₂ (0.5 M) and 0.5 mL of DDT were additionally injected to grow a ZnSe shell to a thickness of 0.6 nm. The synthesized quantum dots were purified twice by a precipitation/redispersion (ethanol/toluene) method.

Compound 1 was added to a blue light-emitting ZnSeTe/ZnSe/ZnS quatum dot solution dissolved in toluene (55 mg/mL) by 20 wt % relative to the quantum dots to prepare a blue quantum dot ink composition.

### Example 1: Manufacture of Quantum Dot Patterned Film Using PIN Photopatterning

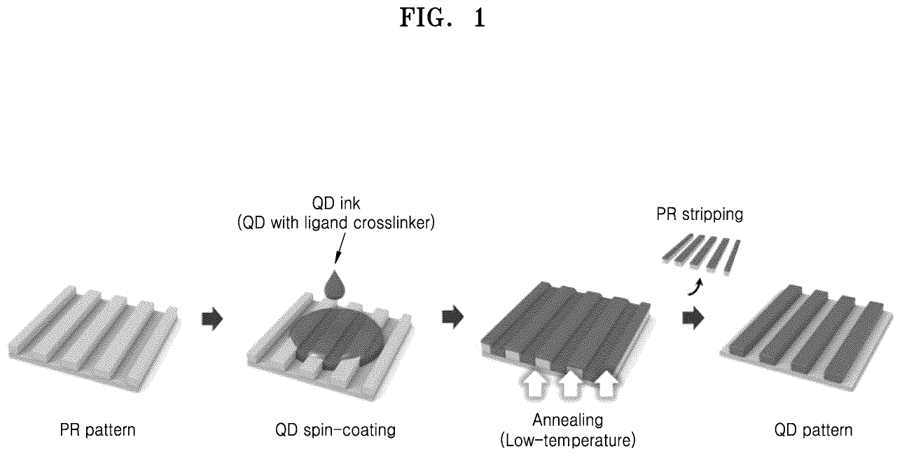

A quantum dot patterned film according to an embodiment may be manufactured by the following method with reference to FIG. 1.

### (1) Formation of Photoresist Pattern (PR Pattern)

A substrate was cleaned in an ultrasonic bath filled with acetone and isopropyl alcohol for 10 minutes, and then dried with a nitrogen gun. KL5301 photoresist (product of Kemlab Incorporation) was applied onto a SiO₂ substrate by a multi-stage spin coating process (500 rpm for 5 s, 4500 rpm for 40 s, and 2000 rpm for 2 s), and the resulting film was soft-baked on a hot plate at 105° C. for 1 minute to form a photoresist film. After the soft baking, the photoresist film was irradiated with UV light (365 nm, 9.8 mW/cm²) for 9 seconds through a photomask using a mask aligner (MDA-400LJ, MIDAS system), and then hard-baked on a hot plate at 115° C. for 1 minute. The hard-baked photoresist film was developed in AZ300MIF developer (product of AZ Electronic Materials) for 4 seconds, and then rinsed with deionized water. The thickness of the resulting photoresist pattern was 70 nm.

### (2) Formation of CdSe/ZnSe/ZnS Quantum Dot Pattern

The red quantum dot ink composition (QD ink) was spin-coated (4,000 rpm, 30 seconds) on a substrate on which the photoresist pattern was formed, and the resulting film was annealed at 110° C. for 20 minutes to induce a crosslinking reaction. Then, the photoresist pattern was stripped in an ultrasonic bath filled with acetone for 1 minute, and then dried using a nitrogen gun to form a CdSe/ZnSe/ZnS quantum dot pattern (QD pattern) having a thicknes of 70 nm.

### Comparative Example 1: Manufacture of Quantum Dot Patterned Film Using Direct Photopatterning

A mixed solution, in which compound 1 (5 wt % relative to quantum dots) was added to a red light-emitting CdSe/ZnSe/ZnS quantum dot solution dissloved in toluene (60 mg/mL), was spin-coated (2,000 rpm for 60 seconds, 25 nm-thick quantum dot pattern, 4,000 rpm for 30 seconds) on a substrate to obtain a film having a thickness of 70 nm. The film was crosslinked with UV (365 nm, 4 mW/cm², corresponding exposure 4.8 J/cm²) through a photomask. Next, the non-crosslinked region of the resulting film was selectively removed using a toluene solvent to develop the quantum dot patterned film of Comparative Example 1 in which a red quantum dot pattern was formed.

### Evaluation Example 1

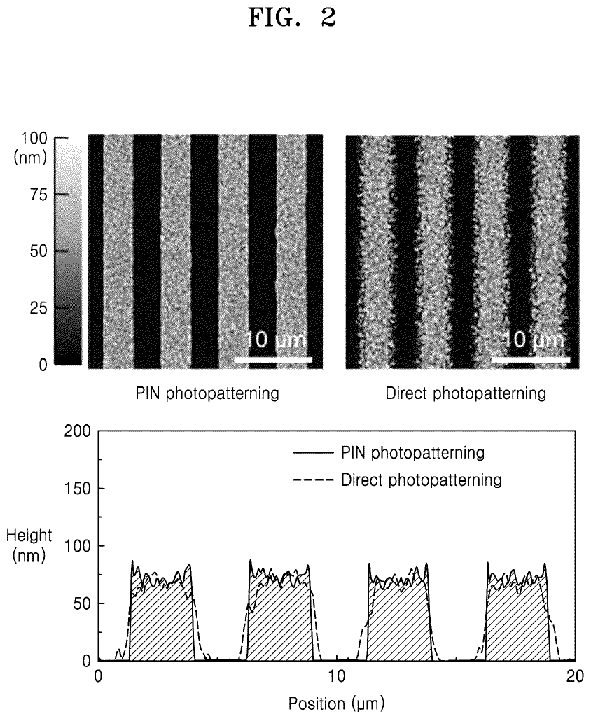

The photographs and height profiles of the quantum dot patterned films manufactured in Example 1 and Comparative Example 1 are shown in FIG. 2, as observed using an atomic force microscope (AFM).

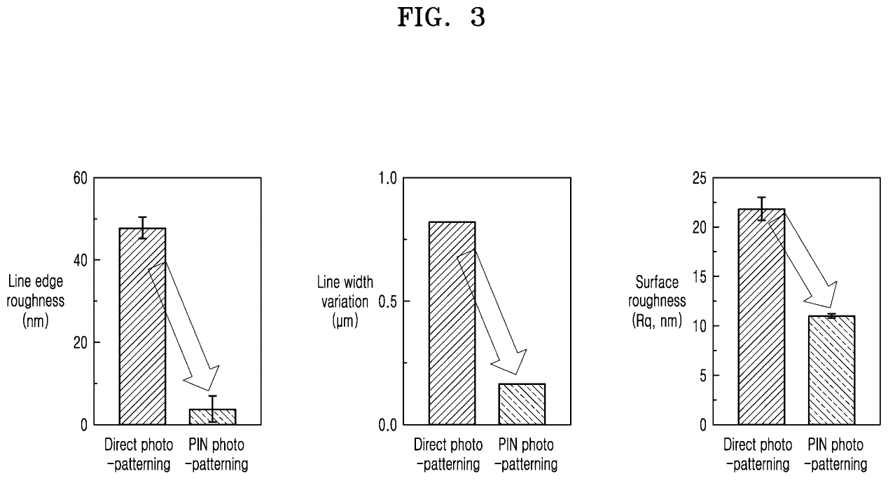

In addition, five or more quantum dot patterned films were manufactured in each of Example 1 and Comparative Example 1, and their line edge roughness, line width variation, and surface roughness were measured, and the results thereof are shown in FIG. 3. In each graph of FIG. 3, the value on the vertical axis is an average value, and the error bar represents a standard deviation.

Referring to FIGS. 2 and 3, it was found that the quantum dot patterned film according to an embodiment had significantly reduced line edge roughness, line width variation, and surface roughness as compared with the quantum dot patterned film of the Comparative Example, thereby exhibiting excellent pattern fidelity.

### Example 2: Manufacture of Multi-Color Quantum Dot Patterned Film

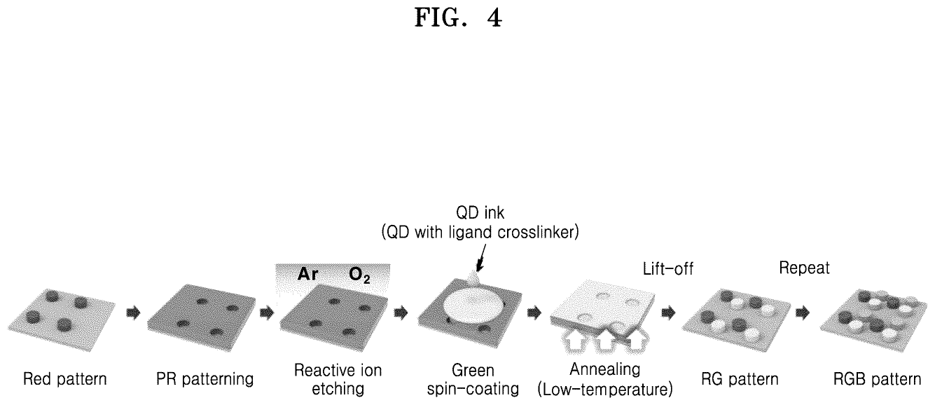

A quantum dot patterned film according to an embodiment may be manufactured into a multi-color quantum dot patterned film by the following method, with reference to FIG. 4.
(1) First, a red light-emitting CdSe/ZnSe/ZnS quantum dot ink composition was patterned using the method described in Example 1 to form a red quantum dot pattern (red pattern).
(2) Then, a photoresist pattern, which is a reverse pattern of a green quantum dot pattern, was formed on a substrate provided with a red light-emitting CdSe/ZnSe/ZnS quantum dot pattern (PR patterning), and plasma-etched to reduce its thickness (reactive ion etching). Since the red light-emitting CdSe/ZnSe/ZnS quantum dot pattern was covered with a photoresist layer, direct exposure to plasma during the etching process could be prevented.
(3) Then, patterning (green spin-coating, annealing, and lifting-off) was performed using a green light-emitting InP/ZnSeS quantum dot ink composition (QD ink) in the same manner as (1) to form red and green quantum dot patterns (RG patterns).
(4) Then, the processes (2) and (3) were repeated using a blue light-emitting ZnSeTe/ZnSe/ZnS quantum dot ink composition to form red (R), green (G), and blue (B) quantum dot patterns (RGB patterns).

### Evaluation Example 2

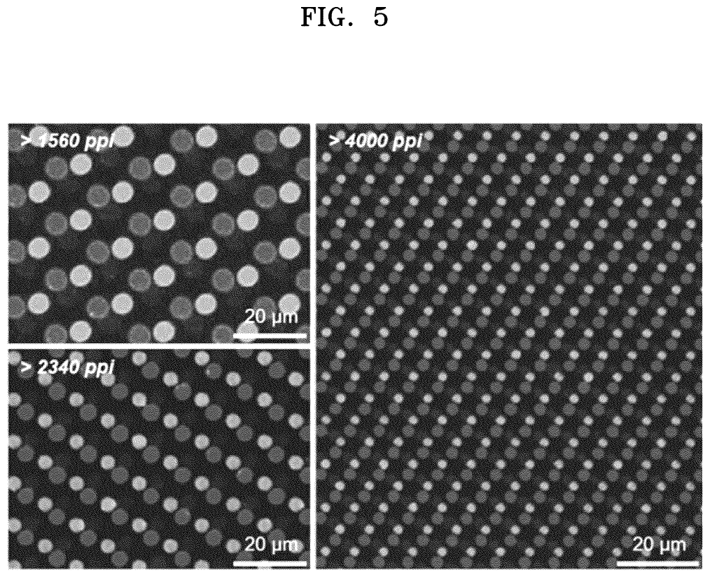

The quantum dot patterned film manufactured in Example 2 was observed using a fluorescence microscope, and the results thereof are shown in FIG. 5.

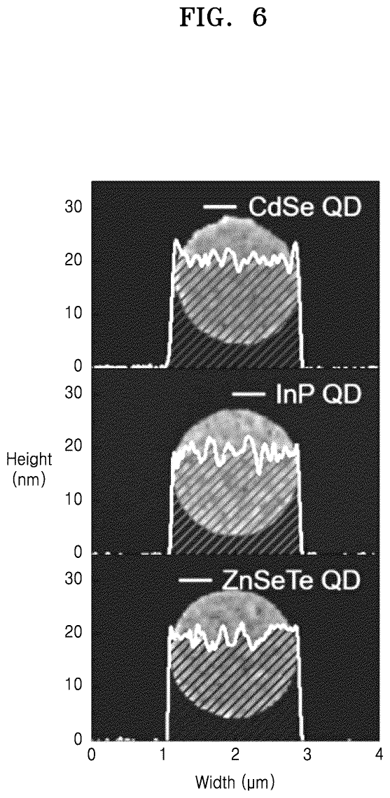

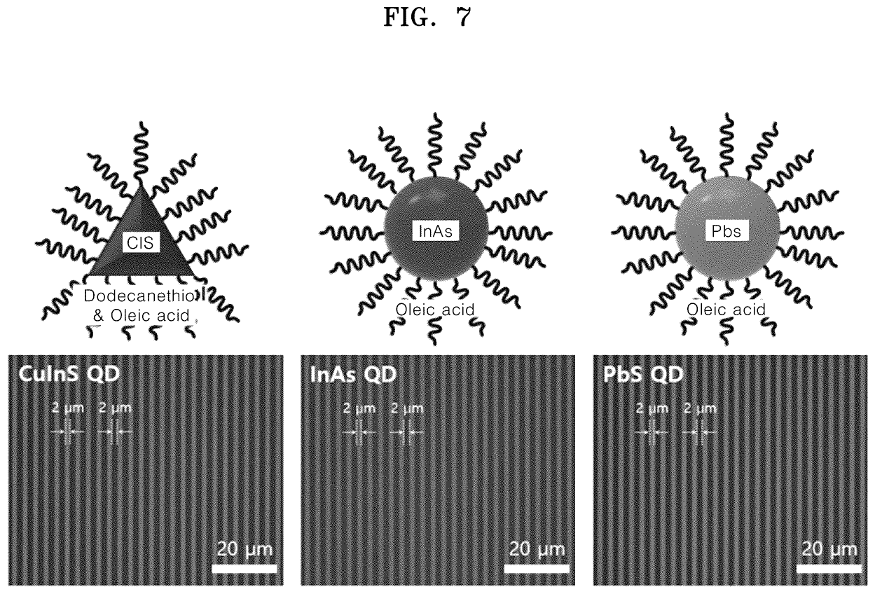

In addition, the photographs and height profiles of the quantum dot film manufactured in Example 2, observed using AFM (atomic force microscopy), are shown in FIG. 6.

Referring to FIGS. 5 and 6, it was found that the quantum dot patterned film according to an embodiment was formed to have RGB quantum dots with excellent fidelity.

### Example 3: Fabrication of Red Light-Emitting Device

A pre-patterned ITO substrate was washed in an ultrasonic bath containing deionized water, acetone, and isopropyl alcohol for 10 minutes, and then dried using a nitrogen gun. The entire QD-LED fabrication was performed under inert conditions.

20 mg/mL ZnO nanoparticles were applied onto the pre-patterned ITO substrate by spin coating at 4,000 rpm for 30 seconds to form a film, and the film was annealed at 80° C. for 30 minutes. 5 wt % of compound 1 was added to 15 mg/mL of red light-emitting CdSe/ZnSe/ZnS QDs and then applied onto ZnO nanoparticles by spin coating at 4,000 rpm for 30 seconds to form a QD film, and the formed QD film was annealed at 110° C. for 20 minutes. CBP (60 nm), MoOₓ (10 nm), and Al (120 nm) were thermally deposited onto the QD films at deposition rates of 0.4 Å/s to 1.0 Å/s, 0.1 Å/s to 0.2 Å/s, and 1.0 Å/s to 2.0 Å/s, respectively, at a pressure of ˜10-7 torr to fabricate a red light-emitting device.

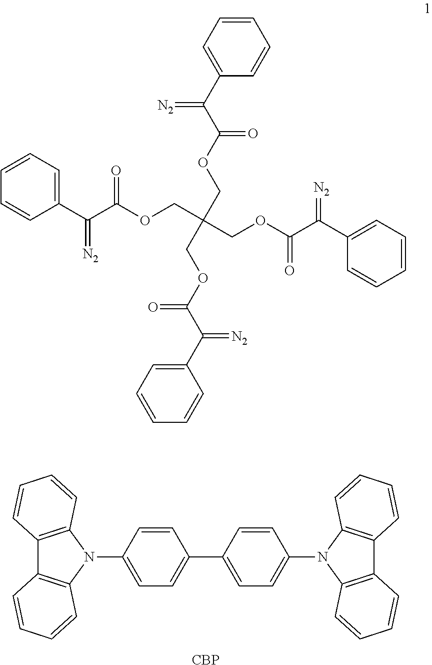

### Example 4: Fabrication of Green Light-Emitting Device

A green light-emitting device was fabricated in the same manner as in Example 3, except that 15 mg/mL of green light-emitting InP/ZnSeS QDs were used instead of 15 mg/mL of red light-emitting CdSe/ZnSe/ZnS QDs when forming the QD film.

### Example 5: Fabrication of Blue Light-Emitting Device

A blue light-emitting device was fabricated in the same manner as in Example 3, except that 10 mg/mL of blue light-emitting ZnSeTe/ZnSe/ZnS QDs were used instead of 15 mg/mL of red light-emitting CdSe/ZnSe/ZnS QDs when forming the QD film.

### Comparative Examples 2 to 4

A red light-emitting device, a green light-emitting device, and a blue light-emitting device were fabricated in the same manners as in Examples 3 to 5, respectively, except that compound 1 was not used when forming the QD film.

### Evaluation Example 3: Evaluation of Characteristics of Light-Emitting Devices

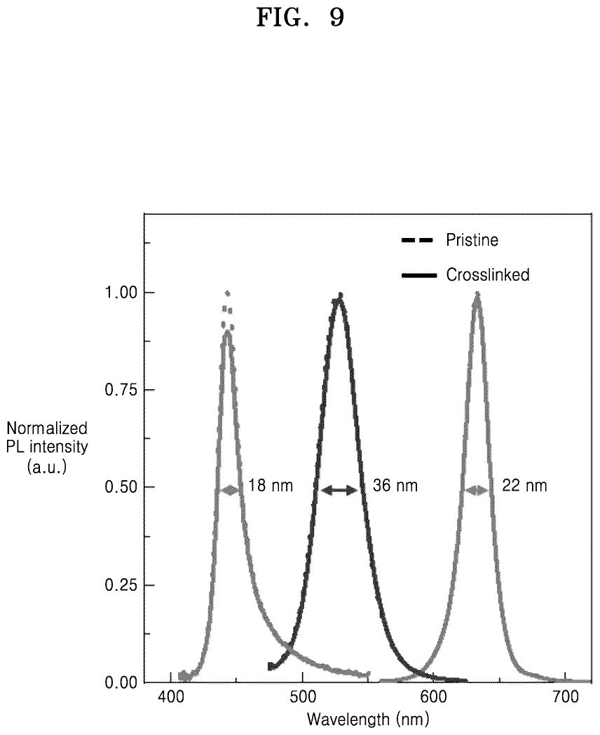

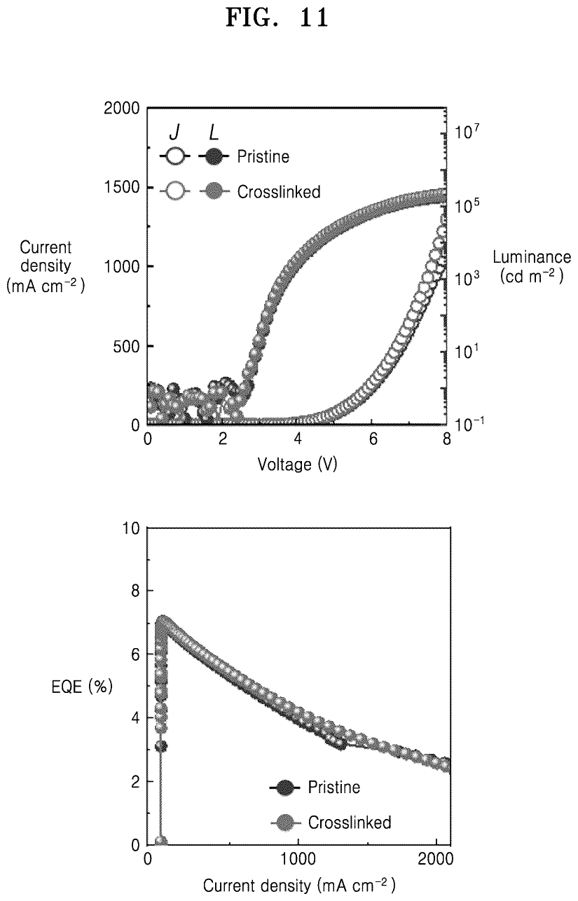

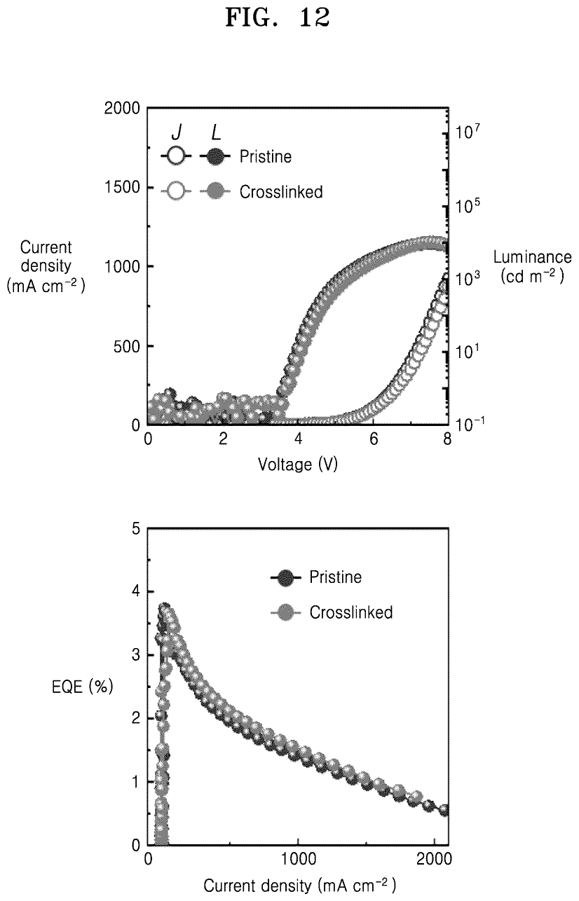

The emission spectra, current density, luminance, and external quantum efficiency (EQE) of the light-emitting devices fabricated in Examples 3 to 5 and Comparative Examples 2 to 4 were measured using Keithley MU 236 and a luminance meter PR650, respectively, and the results thereof are shown in FIGS. 9 to 12.

Referring to FIG. 9, it was found that the emission spectra of the light-emitting devices of Examples 3 to 5 (“Crosslinked”) were similar to the emission spectra of the light-emitting devices of Comparative Examples 2 to 4 (“Pristine”) to such a degree that it was difficult to distinguish the emission spectra of the light-emitting devices of Examples 3 to 5 from the emission spectra of the light-emitting elements of Comparative Examples 2 to 4.

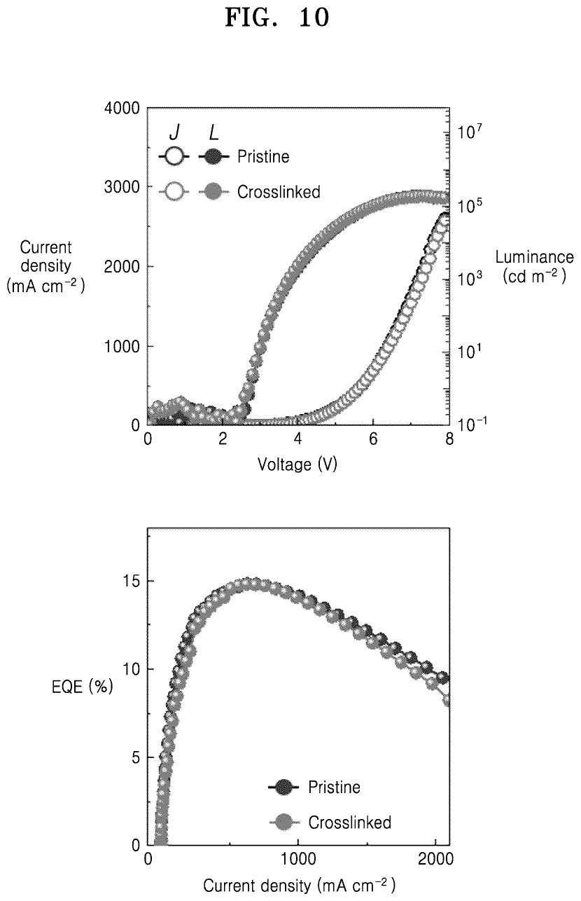

In addition, referring to FIGS. 10 to 12, it was found that the current density (J)-voltage (V)-luminance (L) profiles and external quantum efficiency (EQE)-J profiles of the light-emitting devices of Examples 3 to 5 (“Crosslinked”) were very similar to those of the light-emitting devices of Comparative Examples 2 to 4 (“Pristine”).

From this, it was found that the use of a low-temperature-active crosslinker does not deteriorate the electrical and optoelectronic properties of a QD layer, and that the photopatterning process using the colloidal particle ink composition according to an embodiment is non-destructive.

A colloidal particle pattern formed using the colloidal particle ink composition may have high fidelity and may have reduced line edge roughness and surface roughness. In addition, when forming a colloidal particle pattern using the colloidal particle ink composition, since the colloidal particles are crosslinked by a low-temperature-active crosslinker, a crosslinking reaction can occur without a high-temperature heat treatment, and since the chemical crosslinking reaction provides excellent chemical durability and/or resistance to solvents, a high-quality multi-color colloidal particle pattern can be formed by repeating the application and patterning of ink as needed. Furthermore, cross-linking and patterning can be performed for various colloidal particles having various dimensions or having luminescent or non-luminescent properties.

Although the disclosure has been described with the above embodiments, these are merely exemplary, and those skilled in the art belonging to the disclosure will understand that various modifications and equivalent other embodiments are possible therefrom. Therefore, the true technical protection scope of the disclosure should be determined by the technical idea of the appended claims.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure as defined by the following claims.

What is claimed is:

1. A colloidal particle ink composition comprising: colloidal particles; and a low-temperature-active crosslinker.

2. The colloidal particle ink composition of claim 1,
wherein the colloidal particles include a semiconductor nanocrystal and an organic ligand bound to a surface of the nanocrystal.

3. The colloidal particle ink composition of claim 2,
wherein the semiconductor nanocrystal is a quantum dot including a core and a shell covering at least a portion of the core.

4. The colloidal particle ink composition of claim 2,
wherein the semiconductor nanocrystal includes a III-VI group semiconductor compound; a II-VI group semiconductor compound; a III-V group semiconductor compound; a III-VI group semiconductor compound; a 1-III-VI group semiconductor compound; a IV-VI group semiconductor compound; a IV group compound; or any combination thereof.

5. The colloidal particle ink composition of claim 2,
wherein the organic ligand includes a C₄-C₃₀ fatty acid or a derivative thereof.

6. The colloidal particle ink composition of claim 1,
wherein the low-temperature-active crosslinker is thermally activated at a temperature of about 0° C. to about 130° C. or activated by ultraviolet light of about 200 nm to about 380 nm to produce an intermediate.

7. The colloidal particle ink composition of claim 1,
wherein the low-temperature-active crosslinker is a compound including a diazo group.

8. The colloidal particle ink composition of claim 1,
wherein the low-temperature-active crosslinker is a compound represented by Formula 1 below: 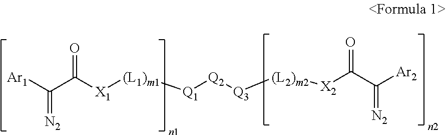
wherein, in Formula 1,
L₁ and L₂ are each independently a single bond or a C₁-C₃₀ alkylene group unsubstituted or substituted with at least one R₁,
m1 and m2 are each independently 1, 2, 3, 4, 5, or 6,
Ar₁ and Ar₂ are each independently a C₅-C₆₀ carbocyclic group unsubstituted or substituted with at least one R₁ or a C₁-C₆₀ heterocyclic group unsubstituted or substituted with at least one R₁,
n1 and n2 are each independently 0, 1, 2, 3, 4, 5, 6, 7, 8, 9, or 10, a sum of n1 and n2 is 2 or more,
Q₁ to Q₃ are each independently a single bond, O, S, C, C(R₂), C(R₂)(R₃), or a C₁-C₃₀ alkylene group unsubstituted or substituted with at least one R₁,
X₁ and X₂ are each independently O, S, Se, N(R₄), or C(R₄)(R₅),
R₁ to R₅ are each independently hydrogen, deuterium, —F, —Cl, —Br, —I, a hydroxyl group, a cyano group, a C₁-C₃₀ alkyl group, a C₂-C₃₀ alkenyl group, a C₂-C₃₀ alkynyl group, a C₁-C₃₀ alkoxy group, a C₁-C₃₀ alkylthio group, a C₅-C₆₀ carbocyclic group, a C₁-C₆₀ heterocyclic group, or —Si(Q₁)(Q₁₂)(Q₁₃), and
Q₁₁ to Q₁₃ are each independently hydrogen, deuterium, —F, —Cl, —Br, —I, a hydroxyl group, a cyano group, a C₁-C₃₀ alkyl group, a C₂-C₃₀ alkenyl group, a C₂-C₃₀ alkynyl group, a C₁-C₃₀ alkoxy group, or a C₁-C₃₀ alkylthio group.

9. The colloidal particle ink composition of claim 8,
wherein the low-temperature activated crosslinker is a crosslinking compound represented by Formula 2 below: 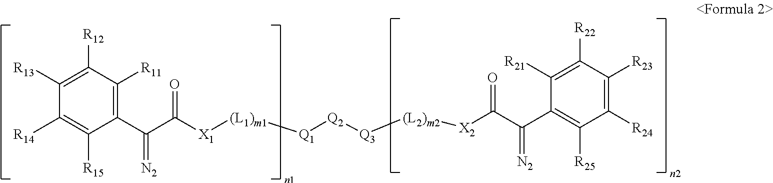
wherein, in Formula 2,
definitions of L₁, L₂, m1, m2, n1, n2, X₁, X₂ and Q₁ to Q₃ are the same as those in claim 8, and
definitions of R₁₁ to R₁₅ and R₂₁ to R₂₅ are each independently the same as that of R₁ in claim 8.

10. The colloidal particle ink composition of claim 1,
wherein the low-temperature activated crosslinker, which is a crosslinkable compound, is at least one selected from Compounds 1 to 7:

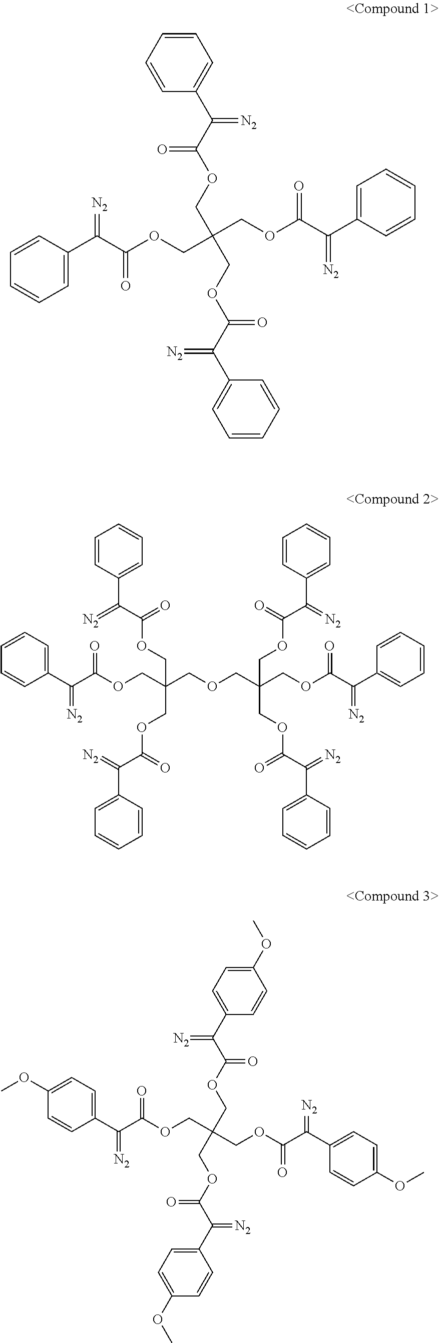

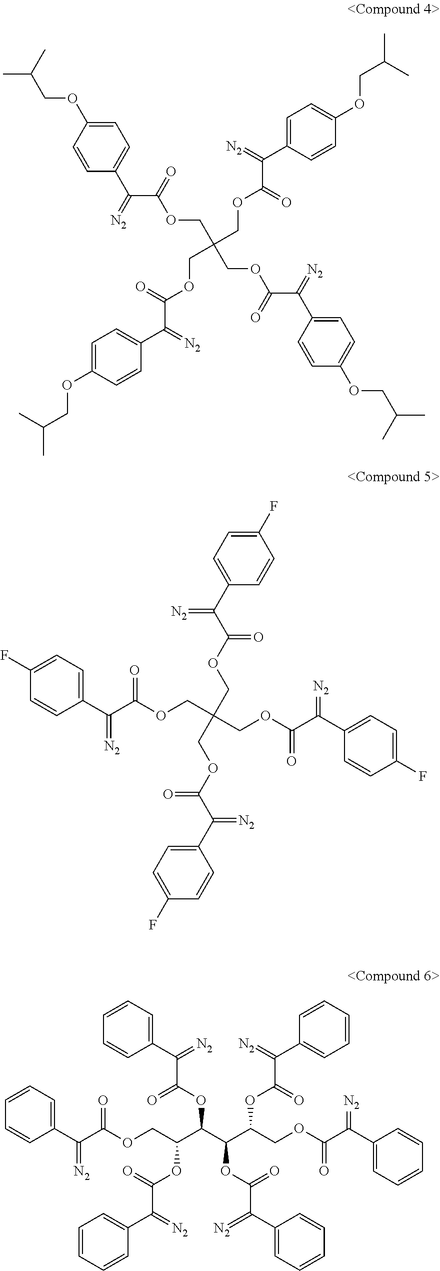

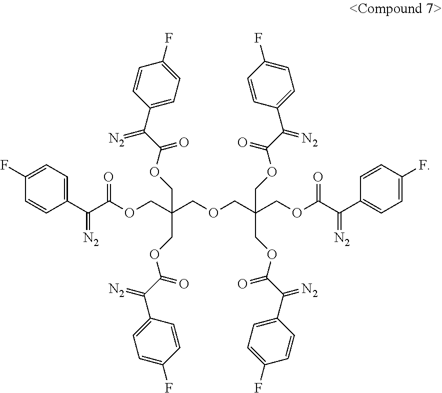

11. A method of forming a colloidal particle pattern by using the colloidal particle ink composition of claim 1.

12. The method of claim 11, comprising:
applying a first colloidal particle ink composition including first colloidal particles and a first low-temperature-activated crosslinker onto a first photoresist pattern;
annealing the applied first colloidal particle ink composition at a temperature of about 0° C. to about 130° C.; and
removing the first photoresist pattern to form a first colloidal particle pattern.

13. The method of claim 12,
wherein a ratio of a thickness of the first photoresist pattern to a thickness of the first colloidal particle pattern is about 1:1 to about 1:0.7.

14. The method of claim 12, further comprising:
reducing the thickness of the first photoresist pattern and/or the thickness of the first colloidal particle pattern by plasma etching.

15. The method of claim 12, comprising:
forming a second photoresist pattern on the first colloidal particle pattern;
applying a second colloidal particle ink composition including second colloidal particles and a second low-temperature-active crosslinker onto the second photoresist pattern;
annealing the applied colloidal particle ink composition at a temperature of about 0° C. to about 130° C.; and
removing the second photoresist pattern to form a second colloidal particle pattern,
wherein the first colloidal particles and the second colloidal particles exhibit different colors from each other.

16. A colloidal particle patterned film formed using the colloidal particle ink composition of claim 1.

17. The colloidal particle patterned film of claim 16, comprising:
a substrate; and a colloidal particle pattern formed on the substrate,
wherein the colloidal particle pattern has a thickness of about 1 nm to about 50 nm.

18. An electronic device comprising a colloidal particle pattern formed using the colloidal particle ink composition of claim 1.

19. The electronic device of claim 18,
wherein the electronic device is a thin-film transistor (TFT), an electrochromic device (EC), a light-emitting diode (LED), a solar cell, or a photodiode.

20. The electronic device of claim 18,
wherein the electronic device is a colloidal particle light-emitting device,
the colloidal particle light-emitting device includes a first electrode, a second electrode facing the first electrode, an intermediate layer between the first electrode and the second electrode and including a light-emitting layer, and
the light-emitting layer includes the colloidal particle pattern.
